(19) United States
(12) Patent Application Publication
(10) Pub. No.: US 2025/0076713 A1
(43) Pub. Date: Mar. 6, 2025

(54) DISPLAY DEVICE, DISPLAY APPARATUS AND COMPOSITE ADHESIVE TAPE FOR A DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Yang Shi, Beijing (CN); Rui Guo, Beijing (CN); Bochang Wang, Beijing (CN); Xiaodi Sun, Beijing (CN); Tianyang Han, Beijing (CN)

(21) Appl. No.: 18/556,065

(22) PCT Filed: Jun. 2, 2022
(86) PCT No.: PCT/CN2022/096872

§ 371 Date: Oct. 18, 2023

(51) Int. Cl. G02F 1/1345; H01L 25/16; H01L 27/12; H05K 1/02

(52) U.S. Cl. CPC G02F 1/13452; H01L 25/167; H05K 1/0203; H10D 86/441; H10D 86/60; H05K 2201/10136

(57) ABSTRACT

The present disclosure provides a display device comprising: a display panel having a light-exiting upper surface, a lower surface opposite to the light-exiting upper surface and a plurality of side edge end surfaces between the light-exiting upper surface and the lower surface, and having a first group of bonding electrodes at a side where a first side edge end surface in the plurality of side edge end surfaces is located; a first flexible circuit board electrically connected to the first group of bonding electrodes; a first insulating protection layer at a side of the first flexible circuit board away from the first group of bonding electrodes, wherein its upper edge is higher than an upper edge of the first flexible circuit board, and its lower edge is lower than the first group of bonding electrodes; a first conductive layer; and a first adhesive layer. The present disclosure also provides a display apparatus comprising the display device and a composite adhesive tape for a display device.

### CROSS-REFERENCE TO RELATED APPLICATION(S)

This application is a Section 371 National Stage Application of International Application No. PCT/CN2022/096872, filed on Jun. 2, 2022, entitled “DISPLAY DEVICE, DISPLAY APPARATUS AND COMPOSITE ADHESIVE TAPE FOR A DISPLAY DEVICE”, which is incorporated herein in entirety by reference.

### TECHNICAL FIELD

The present disclosure relates to the technical field of display, and particularly to a display device, a display apparatus and a composite adhesive tape for a display device.

### BACKGROUND

Currently, there is an increasing demand for large area display, especially in the application scenarios such as security, monitoring and advertising display. However, large-size display apparatuses are expensive, and the largest size thereof cannot fully meet the requirements in the above application scenarios yet.

The requirements for large area display in the above application scenarios may be met by splicing a plurality of display devices together in an array to form a larger display apparatus. Such display devices may be referred to as display units for splicing. Examples thereof may be, for example, a 46-inch display, a 55-inch display, and the like.

In a display apparatus formed by splicing, a gap present between the display areas of adjacent display units for splicing is referred to as a splice seam, which has significant effect on the performances of the final display apparatus. A narrower splice seam results in that there is no obvious interruption or separation between images displayed by adjacent display devices, which contributes to improving the display quality of the final display apparatus and brings a better watching experience. Further, the position of the splice seam may be utilized for a conductive path, which conducts accumulated electrostatic charges or an external charge surge on the front surface of the display device to the back surface of the display device which may be regarded as grounded.

The display panel (such as a liquid crystal panel) in a display device is driven by an external circuit. The circuit for the display panel may be connected to the external drive circuit for the display panel via an interface in a bonding region. Typically, the external drive circuit may comprise a drive circuit board and a flexible circuit board for connection. One end of the flexible circuit board is connected to the bonding electrodes in the bonding region of the display panel, and the other end may be connected to the drive circuit board. A flexible circuit board with a drive chip such as a chip on flex or chip on film (COF) may be used.

In order to make the frame of the display device narrower, the bonding region for bonding the display panel to the external drive circuit has been disposed on the side edge end surface of the display panel. As compared to the case where the bonding region is disposed on the back side of the display panel, disposing the bonding region on the side edge end surface of the display panel may result in that the black matrix region at the frame of the display panel does not need to shield the bonding region. Therefore, the black matrix may become narrower, thereby achieving the effect of making the frame narrower.

In such a configuration, the flexible circuit board connected to the bonding region extends along the side edge end surface of the display panel at the splice seam. It is necessary to avoid that the flexible circuit board at the splice seam is in electrical communication with the conductive path at the aforementioned splice seam, leading to electric leakage. Furthermore, the flexible circuit board also needs sufficient heat dissipation. Therefore, the structure at the splice seam at the side edge end surface of the display device needs to realize electrical conduction, insulating protection and heat dissipation simultaneously while allowing the splice seam to be as narrow as possible.

There is still a need for a display apparatus with good splice seam performance formed by splicing.

### SUMMARY

In an aspect, the present disclosure provides a display device comprising:
a display panel having a light-exiting upper surface, a lower surface opposite to the light-exiting upper surface and a plurality of side edge end surfaces between the light-exiting upper surface and the lower surface, wherein the display panel comprises a first group of bonding electrodes at a side where a first side edge end surface in the plurality of side edge end surfaces is located;
a first flexible circuit board electrically connected to the first group of bonding electrodes, wherein an upper edge of the first flexible circuit board is lower than an upper edge of the first side edge end surface;
a first insulating protection layer at a side of the first flexible circuit board away from the first group of bonding electrodes, wherein an upper edge of the first insulating protection layer is higher than the upper edge of the first flexible circuit board, and a lower edge of the first insulating protection layer is lower than the first group of bonding electrodes;
a first conductive layer comprising a first portion extending along the light-exiting upper surface of the display panel and a second portion extending along the first side edge end surface, wherein the first insulating protection layer is between the second portion and the first flexible circuit board; and
a first adhesive layer at a side of the first conductive layer close to the display panel, wherein the first insulating protection layer is between the first adhesive layer and the first flexible circuit board or between the first adhesive layer and the first conductive layer.

Optionally, the first insulating protection layer comprises an organic insulating film and a heat conductive layer at a side of the organic insulating film close to the first flexible circuit board.

Optionally, a material for the heat conductive layer comprises one or more selected from the group consisting of carbon particles, silica gel and heat conductive oil.

Optionally, the heat conductive layer has a thickness in a range from 0.003 mm to 0.01 mm.

Optionally, the organic insulating film comprises a heat conductive filler permeation region disposed within the organic insulating film and at a side of the organic insulating film close to the heat conductive layer,
wherein the heat conductive filler permeation region comprises a heat conductive filler which is the same as a material for the heat conductive layer.

Optionally, a material for the organic insulating film comprises polyimide.

Optionally, the organic insulating film has a thickness in a range from 0.008 mm to 0.014 mm.

Optionally, the first insulating protection layer further comprises a light shielding film at a side of the heat conductive layer away from the first conductive layer.

Optionally, a material of the first conductive layer comprises aluminum; and the first conductive layer is in direct contact with the first insulating protection layer.

Optionally, a total width of the first conductive layer between the upper edge of the first insulating protection layer and an upper end of the conductive layer is in a range from 0.2 mm to 1.4 mm.

Optionally, a distance between the upper edge of the first insulating protection layer and the upper edge of the first flexible circuit board is greater than or equal to 0.1 mm.

Optionally, a distance between the upper edge and the lower edge of the first insulating protection layer is greater than or equal to 1.6 mm.

Optionally, the display device further comprises:
a back plate and a supporting intermediate frame disposed between the display panel and the back plate;
wherein the first conductive layer is electrically connected to the back plate.

Optionally, the first adhesive layer is electrically conductive in its thickness direction and electrically insulating in its extending direction.

Optionally, the first conductive layer, the first insulating protection layer and the first adhesive layer form at least a part of a composite adhesive tape.

Optionally, the display panel has a rectangular outer contour and has 4 side edges comprising a first side edge having the first side edge end surface, and the display panel further comprises a second side edge having a second side edge end surface and a second group of bonding electrodes at a side where the second side edge end surface is located, wherein the second side edge is adjacent to the first side edge;
wherein the display device comprises a second flexible circuit board electrically connected to the second group of bonding electrodes, wherein an upper edge of the second flexible circuit board is lower than an upper edge of the second side edge end surface;
a second insulating protection layer at a side of the second flexible circuit board away from the second group of bonding electrodes, wherein an upper edge of the second insulating protection layer is higher than the upper edge of the second flexible circuit board, and a lower edge of the second insulating protection layer is lower than the second group of bonding electrodes;
a second conductive layer comprising a first portion extending along the light-exiting upper surface of the display panel and a second portion extending along the second side edge end surface, wherein the second insulating protection layer is between the second portion of the second conductive layer and the second flexible circuit board; and
a third adhesive layer at a side of the second conductive layer close to the display panel, wherein the second insulating protection layer is between the third adhesive layer and the second flexible circuit board or between the third adhesive layer and the second conductive layer;
wherein the display panel comprises a data line extending along the second side edge and a gate line extending along the first side edge, wherein the data line is connected to the first group of bonding electrodes, and the gate line is connected to the second group of bonding electrodes.

Optionally, the first group of bonding electrodes are disposed on the first side edge end surface; and/or
the display panel comprises an array substrate, wherein the first group of bonding electrodes are disposed at a side of the array substrate towards the light-exiting surface of the display panel at a side where the first side edge end surface is located.

In another aspect, the present disclosure provides a display apparatus, wherein the display apparatus is formed by splicing a plurality of display devices as described above, and light-exiting upper surfaces of the plurality of display devices are in the same plane.

In yet another aspect, the present disclosure provides a composite adhesive tape for a display device comprising:
a conductive layer;
an insulating protection layer at a side of the conductive layer, wherein in at least one direction in which the conductive layer extends, at least one side edge of the insulating protection layer exhibits retraction relative to a corresponding side edge of the conductive layer; and
a first adhesive layer disposed at a side of the insulating protection layer away from the conductive layer or between the conductive layer and the insulating protection layer.

Optionally, the insulating protection layer comprises an organic insulating film and a heat conductive layer at a side of the organic insulating film away from the conductive layer.

Optionally, the organic insulating film is a polyimide film.

Optionally, the insulating protection layer further comprises a light shielding film at a side of the heat conductive layer away from the conductive layer.

Optionally, a material of the conductive layer comprises aluminum; and the conductive layer is in direct contact with the insulating protection layer.

Optionally, a distance of the retraction is in a range from 0.2 mm to 1.4 mm.

Optionally, a width of the insulating protection layer in a direction of the retraction is greater than or equal to 1.6 mm.

### BRIEF DESCRIPTION OF DRAWINGS

FIGS. 1A and 1B show schematic diagrams of display devices, wherein a bonding region of the display panel is disposed on its side edge end surface.

FIG. 2 shows an adhesive tape structure at a side edge end of a display panel of a display unit for splicing in the related art.

FIG. 3 shows another adhesive tape structure at a side edge end of a display panel of a display unit for splicing in the related art.

FIG. 4 shows a schematic appearance view of an embodiment of a composite adhesive tape according to the present disclosure.

FIG. 5 shows a schematic appearance view of another embodiment of a composite adhesive tape according to the present disclosure.

FIG. 6 shows a schematic sectional view of the embodiment of FIG. 4 in the A-A direction.

FIG. 7 shows a schematic diagram of an embodiment of an insulating protection layer in FIG. 6.

FIG. 8 shows a schematic sectional view of the embodiment of FIG. 5 in the A-A direction.

FIG. 9 shows a schematic diagram of an embodiment of an insulating protection layer in FIG. 8.

FIG. 10 shows schematic appearance views of two other embodiments of a composite adhesive tape according to the present disclosure.

FIG. 11 shows a schematic diagram of a structure at a side edge end surface of a display panel in an embodiment of a display device according to the present disclosure.

FIG. 12 shows a schematic diagram of a structure at a side edge end surface of a display panel in another embodiment of a display device according to the present disclosure.

FIG. 13 shows a schematic diagram of a structure at a side edge end surface of a display panel in an embodiment of a display device according to the present disclosure.

FIG. 14 shows a schematic diagram of a display apparatus formed by splicing four display devices together.

FIG. 15 shows a schematic structural diagram of an embodiment of a display device according to the present disclosure.

### DETAILED DESCRIPTION

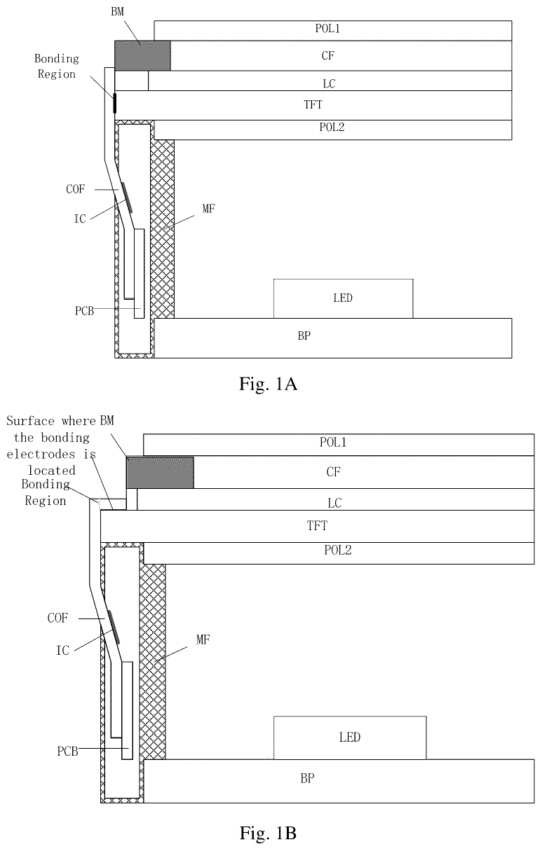

In the related art, in order to make the frame of the display device narrower, the bonding region therein for bonding the display panel to the external drive circuit is disposed on the side edge end surface of the display panel. FIG. 1A and FIG. 1B schematically show schematic diagrams of embodiments of a display device. The figures show the structure near the left end of the display device. The display device comprises a liquid crystal display panel and a display device back plate (BP) supported and separated from each other by an intermediate frame (MF). The liquid crystal display panel is disposed on the top side, and for example, comprises a color film (CF) substrate and a thin film transistor (TFT) array substrate which are cell aligned, and a liquid crystal (LC) layer sandwiched therebetween. An upper polarizer POL1 is provided above the CF substrate, and a lower polarizer POL2 is provided below the TFT array substrate. The left side edge end surface of the upper polarizer may exhibit retraction relative to the left side edge end surface of the CF substrate to form a step. As such, the upper surface of the POL1 and the upper surface of the CF substrate which is not shielded by the POL1 form the upper surface of the display panel. A black matrix (BM) region for shielding light in the frame region may also be provided at the left end of the CF substrate. A bonding region is provided in the middle of the side edge end surface of the display panel. The bonding region refers to a region where the array substrate of the display panel is connected to an external circuit (for example, a flexible circuit board) by a bonding process. Bonding electrodes are led out from the circuit in the display panel, such as the circuit in the array substrate, and for example, are bonded with the flexible circuit board by a bonding process, so as to be electrically connected to an external drive circuit via the flexible circuit board. Typically, the bonding electrodes may be connecting fingers or welding spots, and multiple connecting fingers or welding spots form a single-row or multi-row array to define the bonding region. For example, the bonding region may be a region defined by a row of bonding electrodes. The direction in which the row extends is the width direction of the bonding electrodes, and the direction perpendicular to the width direction is the length direction of the bonding electrodes. In this case, the width of the bonding region is the same as the length of the bonding electrodes in the length direction. For example, the bonding region may be a region defined by multiple rows of bonding electrodes together. The direction in which the row extends is the width direction of the bonding electrodes, and the direction perpendicular to the width direction is the length direction of the bonding electrodes. In this case, the width of the bonding region is the same as the overall length of the multiple rows of bonding electrodes. The overall length represents the length between two points of the multiple rows of bonding electrodes which are farthest from each other, and for example, may comprise the gaps between the bonding electrodes. The bonding region is provided at the side edge of the display panel, and has two typical configurations. The first configuration is such that as shown in FIG. 1A, the bonding electrodes are provided on the side edge end surface of the TFT substrate; and in this case, the bonding region is also located on the side edge end surface of the TFT substrate. The second configuration is such that as shown in FIG. 1B, the edge of the TFT substrate protrudes relative to the edge of the CF substrate to expose a part of surface facing the side of the light-exiting surface of the display panel, and the bonding electrodes are provided on the exposed upper surface; and in this case, the bonding region in a narrow sense should be located on the surface of the TFT substrate facing the side of the light-exiting surface of the display panel, but in the present application, the bonding region in the second configuration is defined as an orthographic projection of the entirety of the bonding electrodes and the flexible circuit board (including the part therebetween) on the surface (for example, a plane) in which the side edge end surface of the TFT substrate is located, as shown by the grey region in FIG. 1B. The bonding region of the present application comprises the bonding region of the first configuration and the bonding region of the second configuration.

It should be noted that the side edge end surface of the display panel as defined in the present application is a surface formed from the translation of the outer contour line of the display panel in the thickness direction of the display panel without exceeding the thickness of the display panel; the side edge end surface of the TFT substrate as defined in the present application is a surface formed from the translation of the outer contour line of the TFT substrate in the thickness direction of the TFT substrate without exceeding the thickness of the TFT substrate; and the side edge end surface of the CF substrate as defined in the present application is a surface formed from the translation of the outer contour line of the CF substrate in the thickness direction of the CF substrate without exceeding the thickness of the CF substrate.

The bonding region may also have other configurations. For example, a portion of bonding electrodes are disposed on the exposed surface of the TFT substrate facing the side of the light-exiting surface of the display panel, and the other portion of bonding electrodes are disposed on the lateral surface of the TFT substrate, and so on. In this case, the definition of the bonding region may be a combination of both configurations as described above. Preferably, the first one saves the most space in the horizontal direction, and can achieve a narrower splice seam. A display device back plate is supported by the lower portion of the intermediate frame, and a backlight source such as LED may be provided on the front surface of the back plate. Light emitted by the backlight source passes through the liquid crystal display panel, and is output from its upper surface, thereby achieving the image display. An external drive control unit of the display panel such as a printed circuit board (PCB) may be accommodated in the cavity structure at the side edge of the intermediate frame. The PCB is electrically connected to the bonding region of the display panel via the flexible circuit board. An example of the flexible circuit board is the chip on flex or chip on film (COF) as shown in the figure, which may have its own drive chip IC thereon. The upper portion of the flexible circuit board is attached and bonded to the bonding region to form an electrical communication, subsequently extends downwards along the side edge end surface of the display panel, and then extends into the cavity structure of the intermediate frame and connects to the PCB. It should be appreciated that no matter which configuration is adopted, in the thickness direction of the TFT substrate, the upper edge of the flexible circuit board at least will not be lower than the upper boundary of the bonding region. For simplicity, when describing the present disclosure, the first configuration may be adopted for the position of the bonding electrodes. Nevertheless, the second configuration and other configurations are also possible. This is not particularly limited in the present disclosure.

In the present disclosure, for simplicity, when describing the section of the multi-layer structure of the display device, unless specifically stated otherwise, the display device is arranged such that its side of the light-exiting surface (i.e., the front surface) is the upper side, and its back side (i.e., the back surface, such as the side of the back plate) is the lower side. When both the display panel and the back plate in the display device are extending in parallel, the display panel is disposed above the back plate, and light is output from the upper surface of the display panel. The side edge end surface of the display device may extend in the thickness direction of the display panel. In the present disclosure, the expressions “up”, “down”, “left”, “right” and the like are all used to describe relative directions rather than absolute directions. When the light-exiting surface of the display device is defined as the upper surface, and the surface on the side of the back plate is defined as the opposite lower surface, an “upper edge” of an object is an edge on the side closer to the light-exiting surface of the display device than its “lower edge”. In this case, when two positions are compared to each other, it may be said that the position at a side closer to the light-exiting surface of the display device is higher than the position closer to the back side.

When a plurality of display devices are used to form a display apparatus of larger size by splicing, a splice seam will be formed at the side edge end surfaces of adjacent display devices facing each other. At the splice seam, it is necessary to provide a conductive path for connecting the upper surface of the display panel and the back plate of the display device, so as to conduct accumulated electrostatic charges or an external charge surge on the front surface of the display device to the back surface of the display device which may be regarded as grounded. For a display device where there is no bonding region on the side edge end surface of the display panel and thus there is no flexible circuit board at the splice seam, such a conductive path may be simply achieved by an electrically conductive adhesive tape covering the side edge of the display device. The body of the electrically conductive adhesive tape extends along the side edge end surface, such that the upper end bends and then adheres to the edge of the upper surface of the display panel, and the lower end adheres to the back plate of the display device. However, when the side edge end surface of the display device has a bonding region and is provided with a flexible circuit board, it is necessary to well insulate the region of the flexible circuit board bonded to the bonding electrodes, avoiding that it is in communication with the conductive path extending along the splice seam to affect the display.

Previously, this function is achieved by specially designing the frame structure. Recently, other processes have been utilized for protection, thereby avoiding complex frame structures.

One process in the related art comprises first applying a non-solid state insulating material onto a side of the region of the flexible circuit board bonded to the bonding electrodes away from the bonding electrodes, solidifying the non-solid state insulating material to form a solidified insulating material layer on the flexible circuit board, and then covering the solidified insulating material layer with an electrically conductive adhesive tape (for example, an aluminum foil adhesive tape). In this way, the region of the flexible circuit board bonded to the bonding electrodes is insulated from the electrically conductive adhesive tape because it is covered by the solidified insulating material layer. The electrically conductive adhesive tape forms a conductive path from the front surface of the display device to the back surface of the display device.

This process may effectively protect the region of the flexible circuit board bonded to the bonding electrodes. However, the solidified insulating material layer formed by applying and then solidifying a non-solid state insulating material has a relatively large thickness, and a special applicator is required. This results in a broad splice seam and high production cost. Such a splice seam unit may achieve, for example, a splice seam width of about 2.04 mm. The splice seam width represents a distance between the display areas of two adjacent display devices. The side edge end, which is connected to the flexible circuit board, of one display device is spliced together with the side edge end, which is not connected to the flexible circuit board, of the other display device. The contribution of the display device which is connected to the flexible circuit board to the splice seam width comprises the width of the non-display area of the display panel of 0.67 mm, the thickness of the flexible circuit board of 0.1 mm, the thickness of the solidified insulating material layer of 0.3 mm, and the thickness of the aluminum foil adhesive tape of 0.05 mm. The contribution of the display device which is not connected to the flexible circuit board to the splice seam width comprises the width of the non-display area of the display panel of 0.57 mm, the thickness of the solidified insulating material layer of 0.3 mm, and the thickness of the aluminum foil adhesive tape of 0.05 mm. Because the thickness of the solidified insulating material layer cannot be too small, it is difficult for this process to achieve a splice seam width less than 2 mm.

It should be noted that the above thickness of the flexible circuit board does not include the thickness of an optional reinforcing adhesive layer thereon for reinforcing the bonding structure. Specifically, after an electrical connection is formed between the flexible circuit board and the bonding region by a process such as hot pressing or welding, it is possible to provide an additional reinforcing adhesive layer, such that the flexible circuit board is more firmly bonded to the bonding region, avoiding loosening and detachment of the electrical connection formed only by hot pressing or welding. An example of such a reinforcing adhesive layer may be a UV curable adhesive. If there is such a reinforcing adhesive layer, the splice seam needs to include the thickness of this reinforcing adhesive layer. However, as described below, the composite adhesive tape of the present disclosure may function for reinforcing the bonding of the flexible circuit board to the bonding region, so such a reinforcing adhesive layer may be completely omitted, facilitating the narrowing of the splice seam.

Another process in the related art comprises first using an insulating elastic adhesive tape to adhere to the flexible circuit board on the side edge end surface and covering the region of the flexible circuit board bonded to the bonding electrodes, and then adhering an electrically conductive adhesive tape (for example, an aluminum foil adhesive tape) onto the side edge end surface. Because the region of the flexible circuit board bonded to the bonding electrodes is covered by the insulating elastic adhesive tape, it will not be in communication with the electrically conductive adhesive tape. The insulating elastic adhesive tape may be made by stacking an insulating material layer and an adhesive layer. As compared to the aforementioned solidified insulating material layer, the insulating elastic adhesive tape is manually adhered, no special applicator is required, and the preformed insulating elastic adhesive tape has a thickness significantly less than that of the solidified insulating material layer which is solidified in situ.

Such a splice seam unit may achieve, for example, a splice seam width not less than 1.54 mm, which is composed of the portion between the display areas of two adjacent display device. The side edge end of one display device thereof which is connected to the flexible circuit board is spliced together with the side edge end of the other display device which is not connected to the flexible circuit board. The contribution of the display device which is connected to the flexible circuit board to the splice seam width comprises the width of the non-display area of the display panel of 0.67 mm, the thickness of the flexible circuit board of 0.1 mm, the thickness of the insulating elastic adhesive tape of 0.05 mm, and the thickness of the aluminum foil adhesive tape of 0.05 mm. The contribution of the display device which is not connected to the flexible circuit board to the splice seam width comprises the width of the non-display area of the display panel of 0.57 mm, the thickness of the insulating elastic adhesive tape of 0.05 mm, and the thickness of the aluminum foil adhesive tape of 0.05 mm.

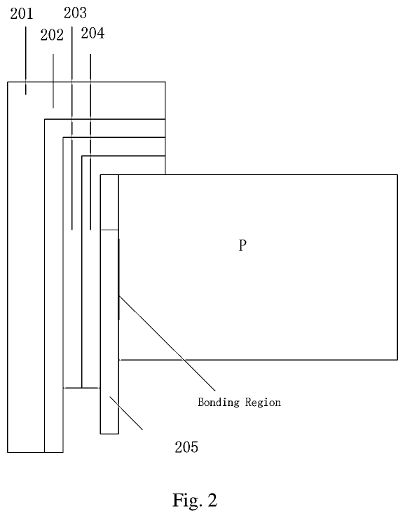

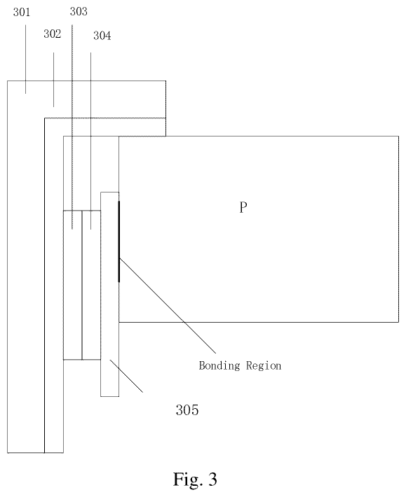

In this process of adhering two adhesive tapes, the position for adhering of the insulating elastic adhesive tape is strictly limited. On one hand, the insulating elastic adhesive tape should not separate the aluminum foil adhesive tape from the upper surface of the display panel. Otherwise, the charges on the upper surface cannot be transferred to the electrically conductive adhesive tape, thereby leading to damage associated with electrostatic charge accumulation or external charge surge. As shown in FIG. 2, a flexible circuit board 205 is bonded on the side edge end surface of a display panel P, and is attached and bonded to a bonding region on the side edge end surface of the display panel. An insulating elastic adhesive tape with an adhesive layer 204 and an insulating layer 203 is adhered onto the side edge end surface, and then an electrically conductive adhesive tape with an adhesive layer 202 and a conductive layer 201 is adhered onto the insulating layer 203. Because the insulating layer 203 separates the electrically conductive adhesive tape 201 from the upper surface of the display panel P to cause insulation, the display panel will be easily damaged due to electrostatic charge accumulation or external charge surge. On the other hand, the insulating elastic adhesive tape must completely cover the region of the flexible circuit board corresponding to the bonding region, otherwise it is possible that the region of the flexible circuit board bonded to the bonding electrodes will lack insulating protection and thus be damaged. Because the upper edge of the flexible circuit board is very close to the bonding region, the insulating elastic adhesive tape needs to cover the upper edge of the flexible circuit board to ensure insulation. As shown in FIG. 3, an insulating elastic adhesive tape with an adhesive layer 304 and an insulating layer 303 and an electrically conductive adhesive tape with an adhesive layer 302 and a conductive layer 301 are adhered a side edge end surface with a flexible circuit board 305 bonded, wherein the insulating elastic adhesive tape does not cover the upper edge of the flexible circuit board 305. After attaching in this way, the upper edge of the flexible circuit board is not covered by the insulating elastic adhesive tape. As a result, there is a risk that the region of the flexible circuit board bonded to the bonding electrodes, which is close to the upper edge of the flexible circuit board, will be in direct contact with the aluminum foil adhesive tape to cause conduction, so that a problem of picture display due to the short circuit of the flexible circuit board may occur, which will greatly affect the stability of product quality. It should be noted that in FIG. 2 and FIG. 3, the gap between the electrically conductive adhesive tape or the insulating elastic adhesive tape and the side edge end surface is only for the purpose of making the schematic diagram more clear. Such a gap may be absent after attaching by pressing in practical, because each adhesive tape has a very small layer thickness and is soft. That is, each adhesive tape is firmly attached to the side edge end surface.

However, because the adhesive tape can only be adhered manually, it is difficult to avoid the problems as shown in FIG. 2 and FIG. 3, thereby resulting in reduced yield.

Furthermore, for each splice seam, this process needs adhering of four pairs of adhesive tapes in total for two display devices, and accordingly, the operation is performed four times. Not only the amount of labor is great, but also each operation of adhering needs to meet strict requirements on the adhering position, thereby resulting in complicated operation for the worker and reduced production efficiency.

Another important problem associated with the flexible circuit board disposed on the side edge end surface is its heat dissipation. During the operation, the flexible circuit board may generate heat. In particular, when a driver chip IC is provided on the flexible circuit board, the heat generation is more obvious. If the heat dissipation efficiency of the flexible circuit board is low, an overly high temperature will cause the problem of abnormal picture under high temperature conditions such as in a high temperature reliability test. For example, when the IC on the flexible circuit board as shown in FIG. 1 generates heat, it will raise the temperature of the entire flexible circuit board. The heat from the flexible circuit board either spreads to the cavity inside the display device, or spreads to the outside of the display device. When the heat spreads to the cavity inside of the display device and accumulates, it will adversely affect the display module, and thus deteriorate the image quality. Therefore, there is a need for enhancing the capacity of dissipating heat from a side of the flexible circuit board away from the display panel.

Although the insulating elastic adhesive tapes in the related art have a good insulating property, they have poor heat dissipation property and are not heat resistant. If an insulating film layer made therefrom is directly overlaid on the flexible circuit board, it is difficult for the heat dissipation property to meet the requirement. In this regard, in the related art, the problem of heat dissipation is solved by adhering separately an individual heat conductive adhesive onto the surface of the flexible circuit board before overlaying the insulating layer. Such a process has a high cost, and the operation is particularly inconvenient especially when there are multiple flexible circuit boards on the side edge end surface. For example, there may be a total of 24 flexible circuit boards on the side edge end surfaces of a typical 55-inch display device, and each flexible circuit board needs a sheet of heat conductive adhesive to be adhered thereon, so a total of 24 times of operation are required. The presence of the heat conductive adhesive may also increase the width of the splice seam.

The embodiments of the present disclosure may at least partially solve the aforementioned problems associated with the thermal conduction, insulation, electrical conduction and adhering operation of the flexible circuit board on the side edge end surface of a display unit for splicing.

In an embodiment, the present disclosure provides a composite adhesive tape for a display device comprising:
a conductive layer;
an insulating protection layer disposed at a side of the conductive layer, wherein in at least one direction in which the conductive layer extends, at least one side edge of the insulating protection layer exhibits retraction relative to a corresponding side edge of the conductive layer; and
a first adhesive layer disposed at a side of the insulating protection layer away from the conductive layer or between the conductive layer and the insulating protection layer.

In a particular embodiment, the first adhesive layer has a width the same as that of the conductive layer.

In a particular embodiment, in a direction of the retraction of the insulating protection layer, a width of the insulating protection layer is less than that of the conductive layer.

In a particular embodiment, the insulating protection layer further comprises a heat conductive layer.

In a particular embodiment, the insulating protection layer comprises an organic insulating film and a heat conductive layer at a side of the organic insulating film away from the conductive layer.

In a particular embodiment, the organic insulating film comprises a heat conductive filler permeation region within the organic insulating film and at a side of the organic insulating film close to the heat conductive layer; wherein the heat conductive filler permeation region comprises a heat conductive filler, which is the same as a material for the heat conductive layer.

In a particular embodiment, the composite adhesive tape of the present disclosure is a strip-shaped product, and has a length direction, a width direction perpendicular to the length direction, and a thickness direction perpendicular to both the length direction and the thickness direction, in which the composite adhesive tape has a much less size. In the width direction of the composite adhesive tape, at least one side edge of the insulating protection layer exhibits retraction relative to a corresponding side edge of the conductive layer, and the direction of the retraction is perpendicular to the length direction.

In a particular embodiment, the composite adhesive tape of the present disclosure comprises: a conductive layer; a first adhesive layer at a side of the conductive layer and having a width the same as that of the conductive layer; an insulating protection layer at a side of the first adhesive layer away from the conductive layer or between the conductive layer and the first adhesive layer, wherein in the width direction of the conductive layer, at least one side edge of the insulating protection layer exhibits retraction relative to the edge of the conductive layer, wherein the insulating protection layer comprises an organic insulating film and a heat conductive layer at a side of the organic insulating film away from the conductive layer. In a particular embodiment, the organic insulating film comprises a heat conductive filler permeation region disposed within the organic insulating film and at a side of the organic insulating film close to the heat conductive layer; wherein the heat conductive filler permeation region comprises a heat conductive filler, which is the same as a material for the heat conductive layer.

It should be noted that the widths direction of the conductive layer, the first adhesive layer and the insulating protection layer of the composite adhesive tape are the same as that of the composite adhesive tape.

The present disclosure provides a composite adhesive tape made by combining multiple layers of materials, which can solve the problems of insulation, electrical conduction and bothersome adhering operation of the flexible circuit board in the display device, and also solve the problem of its heat dissipation, and are particularly suitable as the display device of a display unit for splicing.

Specifically, the display device may comprise a display panel, an intermediate frame and a back plate. The intermediate frame is used for supporting the display panel. The back plate comprises a back plate body at a side of the intermediate frame away from the display panel. In some embodiments, the back plate further comprises a back plate flanging, which may be configured to extend toward the display panel at the edge of the back plate in a direction perpendicular to the back plate body. The display device may further comprise a backlight source disposed between the back plate body and the display panel. The backlight source may be, for example, an edge-lit backlight source or a direct-lit backlight source. Specifically, a light source film layer is further provided between the backlight source and the display panel. The light source film layer may function to homogenize light emitted by the backlight source.

Specifically, the composite adhesive tape of the present disclosure comprises a conductive layer, a first adhesive layer and an insulating protection layer. Here, the conductive layer may be configured to be electrically connected to the front surface of the display panel of the display device and the back plate of the display device respectively to ground the display panel. The conductive layer may be in direct contact with the back plate to form an electrical connection, or may be electrically connected to the back plate via an electrically conductive adhesive.

In a particular embodiment, when the composite adhesive tape is adhered on the display device, the composite adhesive tape is adhered along the side edge end surface of the display panel, and its width direction is consistent or approximately consistent with the thickness direction of the side edge end surface. Preferably, in the thickness direction of the side edge end surface of the display panel, the conductive layer extends a distance such as to ensure that it may be connected to the back plate. The entire width of the conductive layer may be greater than the thickness of the edge of the display device. Specifically, the conductive layer may bend toward a side of the back plate body away from the display panel (i.e., the back surface of the back plate) and be adhered thereon. In this way, after adhering, the composite adhesive tape may form a conductive path from the front surface of the display panel to the back plate, and the composite adhesive tape is in sufficient contact with the back plate body, ensuring that external charges in contact with the front surface of the display panel may rapidly flow back to the back plate (which may be regarded as grounded). When the display panel is in the cases of electrostatic charge accumulation or external charge surge, the circuit of the display panel itself will not be affected or damaged, ensuring normal display. If the back plate has a back plate flanging, the conductive layer may also not bend toward the side of the back plate body away from the display panel, and may be directly adhered to the flanging. In sum, the conductive layer is used to conduct charges on the front surface of the display device as the display unit for splicing to the back surface; and when the conductive layer may be adhered to the side of the back plate body away from the display panel, the adhesion between the composite adhesive tape and the display panel may be increased.

Specifically, the conductive layer may be adhered to the display device via a first adhesive layer, wherein the first adhesive layer comprises an electrically conductive adhesive. For example, the first adhesive layer is an acrylic adhesive layer.

On the front surface of the display panel, the adhering of the composite adhesive tape may be designed such that the conductive layer may bend from the side edge end surface of the display panel toward its light-exiting surface and extends at the edge of the display panel along a direction in parallel to the plane where the light-exiting surface of the display panel is located (for example, the surface of the color film substrate or the polarizer) to direct out charges on the light-exiting surface of the display panel. The bending width of the conductive layer preferably does not enter into the display area of the display panel.

Specifically, the width of the conductive layer is the width of the composite adhesive tape. Typically, the width of the conductive layer may be in a range from 25 to 45 mm, such as 35 mm. Such a width is suitable for a current conventional display device.

In a particular embodiment, the conductive layer is preferably an aluminum foil. Various conventional aluminum foils in the field of electronic device may be used. A typical thickness of the aluminum foil is in a range from 0.03 to 0.04 mm, such as 0.036 mm.

In a particular embodiment, the first adhesive layer is a layer to provide adhesion for the composite adhesive tape, such that the composite adhesive tape may be adhered to the side edge end surface and light-exiting surface of the display unit for splicing. The first adhesive layer is at a side of the conductive layer, and has a width the same as that of the conductive layer. In other words, the first adhesive layer is completely overlapped with the conductive layer. As such, it may be ensured that the entire conductive layer is firmly adhered. The first adhesive layer also has an electrical conductivity in the thickness direction, enabling electrical conduction between the conductive layer adhered thereby and the surface being adhered.

In a particular embodiment, a common pressure-sensitive adhesive may be used as the first adhesive. Typically, a conventional adhesive in an electrically conductive aluminum foil in the related art is used. An example of the pressure-sensitive adhesive is an acrylic adhesive. A typical thickness of the first adhesive layer is in a range from 0.012 to 0.016 mm, such as 0.014 mm.

In a particular embodiment, a sum of the thicknesses of the conductive layer and the first adhesive layer may be, for example, 0.05 mm.

In a particular embodiment, the composite adhesive tape of the present disclosure has an insulating protection layer, wherein the insulating protection layer comprises an organic insulating film and a heat conductive layer at a side of the organic insulating film away from the conductive layer. When the composite adhesive tape is adhered to the display device, the heat conductive layer is designed to be close to the flexible circuit board, so as to timely direct out the heat from the flexible circuit board. Preferably, the organic insulating film comprises a heat conductive filler permeation region disposed within the organic insulating film and at a side of the organic insulating film close to the heat conductive layer; wherein the heat conductive filler permeation region comprises a heat conductive filler, which is the same as a material for the heat conductive layer. When a heat conductive layer is provided on the surface of the organic insulating film, the material of the heat conductive layer may permeate into the surface of the organic insulating film as a heat conductive filler, thereby forming a heat conductive filler permeation region. As compared to an inorganic insulating layer, the organic insulating film may realize the heat conductive filler permeation region formed in the surface thereof more easily, and may be prepared in the form of adhesive tape to facilitate the mounting operation. The inventors have found that when the organic insulating film itself has a poor thermal conductivity, in order to provide good heat dissipation to the flexible circuit board close to the organic insulating film, a heat conductive layer may be formed on a surface of the organic insulating film away from the conductive layer. The heat conductive layer is formed on the surface of the organic insulating film away from conductive layer, such that it is close to the flexible circuit board after adhering to provide heat dissipation for the flexible circuit board. The heat conductive layer may at least rapidly homogenize non-uniform heats generated from various positions of the flexible circuit board in the entire heat conductive layer, and may then further dissipate the heats. In a particular embodiment, the material of heat conductive layer may be used as a heat conductive filler to permeate into the surface of the organic insulating film, thereby forming a heat conductive filler permeation region. The heat conductive filler permeation region may help the heat conductive layer to be better fixed to the organic insulating film.

In an embodiment, the heat conductive layer and the heat conductive filler permeation region may be formed by treating a surface of the organic insulating film with a heat conductive filler. The surface treatment comprises treating with a heat conductive filler after the organic insulating film is formed or before the precursor of the organic insulating film is converted into the organic insulating film. For example, for polyimide (PI), after forming a PI film, a heat conductive filler may be stamped onto the surface of the PI film by hot stamping, thereby forming a heat conductive layer and a heat conductive filler permeation region. The heat conductive filler may also permeate to form the heat conductive layer and the heat conductive filler permeation region before preparing PI from polyamic acid (PAA). Typically, the PI film is prepared by steps of: preparing a PAA solution by polymerizing a dianhydride and a diamine in a solvent; casting the PAA solution to form a PAA liquid film; drying the PAA liquid film to form a PAA solid film; orientation stretching the PAA solid film into a strip-shaped PAA film; and dehydrating and catalyzing the strip-shaped PAA film to form a strip-shaped PI film. In this process, particles of the heat conductive filler may be provided to the surface of the PAA film in the process of drying the PAA liquid film into the PAA solid film, and thus the final strip-shaped PI film may have a heat conductive filler permeation region and a heat conductive layer on its surface. The particles of the heat conductive filler may be carbon particles, such as graphite particles, diamond particles, etc. Among them, graphite particles are preferable due to the high thermal conductivity and low cost thereof.

The insulating protection layer formed from the heat conductive layer and the organic insulating film together is integral, facilitating subsequent adhering operation. As compared to the case where an additionally prepared heat conductive film layer is separately provided to the flexible circuit board and the side edge end surface of the display panel, it is much more convenient to achieve thermal conduction while the insulating film layer is adhered.

The heat conductive layer has a width the same as that of the organic insulating film. Although the heat conductive layer may be provided only in a partial region of the organic insulating film, from the viewpoint of the simplicity of preparation, the simplicity of application, and the thermal conduction reliability, it is suitable to completely covering one side of the organic insulating film with the heat conductive layer. It is simple and convenient to provide the heat conductive layer entirely on one side of the organic insulating film in view of design and preparation. Furthermore, this may also allow the entire surface of the organic insulating film to have thermal conductivity, facilitating thermal conduction. A larger heat conductive layer is also more tolerant to positional errors which may be caused by manually adhering.

In a particular embodiment, the insulating protection layer is disposed at a side of the conductive layer, and in the width direction in which the conductive layer extends, an edge at one end or edges at both ends of the insulating protection layer exhibits retraction relative to edges at both ends of the conductive layer. When the composite adhesive tape is adhered on the display device, a side edge of the insulating protection layer close to the light-exiting surface of the display panel exhibits retraction toward the back plate body relative to the corresponding side edge of the conductive layer, thereby ensuring that the electrical conduction between the conductive layer and the light-exiting surface of the display panel will not be impeded. A side edge of the insulating protection layer close to the back plate body may also exhibit retraction toward the light-exiting surface of the display panel relative to the corresponding side edge of the conductive layer, thereby ensuring that the electrical conduction between the conductive layer and the back plate will not be impeded. In a particular embodiment of the present disclosure, an insulating protection layer comprising a heat conductive layer and a heat conductive filler permeation region and having particular width and positional design may cover the position (for example, a bonding region) on the side edge end surface of the display device for bonding the flexible circuit board to the display panel, to provide reliable protection which may be easily achieved manually, avoiding the risk of the contact between the flexible circuit board and the conductive layer during adhering and the risk of the insulation of the conductive layer from the display panel. Meanwhile, the composite adhesive tape also provides good heat dissipation for the flexible circuit board. Besides, the composite adhesive tape of the present invention may also function to mechanically reinforce the bonding of the flexible circuit board to the bonding electrodes. The aforementioned reinforcing adhesive layer process may be omitted by using the composite adhesive tape of the present invention, thereby saving the cost. Preferably, there is no need to use the aforementioned reinforcing adhesive layer.

In a particular embodiment, the organic insulating film may be a polyimide (PI) film or a polyethylene terephthalate (PET) film.

Preferably, the organic insulating film of the present disclosure is a polyimide (PI) film. The insulating protection layer may be a monolayer polyimide film or a stack comprising a polyimide film. Specifically, the PI film has significant advantages in properties of surface resistance, volume resistance, heat distortion temperature and coefficient of thermal expansion over the PET film, and is inferior to the PET film only in tensile strength. However, in the present disclosure, the insulating protection layer is combined with the conductive layer and the adhesive layer to form the composite adhesive tape, and the mechanical properties such as the shape retention and the elasticity may be provided by the conductive layer. Therefore, in the composite adhesive tape of the present disclosure, the PI film, which is superior in the other properties, is preferably used for the insulating protection layer.

Table 1 below shows a comparison of properties between the PI film and the PET film in the insulating elastic adhesive tape.

TABLE 1

| Property | PI film | PET film | Unit |
|---|---|---|---|
| Tensile strength | 135 | 152 | MPa |
| Surface resistance | 1.0 × 10¹⁶ | 1.0 × 10¹⁵ | Q |
| Volume resistance | 1.0 × 10¹⁵ | 1.0 × 10¹⁴ | Ω · m |
| Heat distortion temperature | 260 | 120 | ° C. |
| Coefficient of thermal expansion | 3.6 × 10⁻⁵ | 6 × 10⁻⁵ | m/° C. |

As can be seen, the PI film is inferior to the PET film only in tensile strength, but is superior to the PET film in the other properties. Both the surface resistance and volume resistance of the PI film are higher by one order of magnitude than those of the PET film, so when comparing the composite adhesive tape of the present disclosure with the aforementioned second approach, in the case of the same thickness, the insulating protection effect on the electric leakage of the flexible circuit board may be increased by 10 times. In other words, the use of a thinner PI film may achieve the same insulating performance as that achieved by using a thicker PET film, thereby allowing a narrower splice seam. Furthermore, the PI film has a heat distortion temperature approximately twice higher than that of the PET film, such that it may be more suitable for the application in tropical areas and may work normally under extreme conditions of hot outdoors. The PI film has a coefficient of thermal expansion approximately only a half of that of the PET film, such that the expansion or contraction of the PI film itself in a high temperature or low temperature environment may be maintained in a very low range. Taking a 55-inch product as an example, the size of its length is 1200 mm, and with a temperature rise of 60° C., its own size change is only 1 mm at one side. This may significantly reduce the problem of glue failure due to size change arising from the expansion or contraction of a product in a high temperature or low temperature environment. Although the mechanical properties of the PI film are inferior to those of the PET film, as described above, the conductive layer in the composite adhesive tape of the present disclosure provide sufficient mechanical properties, such that workers will not encounter the problem of adhesive tape distortion in the adhering operation.

In addition, in the composite adhesive tape of the present disclosure, it is not adding an insulating layer simply on an electrically conductive adhesive tape having a conductive layer and an adhesive layer, but there is a special geometric design. Specifically, in at least one direction in which the conductive layer extends (for example, in the width direction), at least one side edge of the insulating protection layer exhibits retraction relative to a corresponding side edge of the conductive layer.

Specifically, the insulating protection layer of the present disclosure may have a width smaller than the outer size of the composite adhesive tape. In other words, on at least one end, preferably both ends, in the width direction, the edges of the conductive layer and the adhesive layer have portions protruding relative to the insulating protection layer.

As described in detail below, such a special geometric design in the present disclosure may achieve technical effects of simplifying the adhering operation, increasing the production efficiency for the splicing display panel, and increasing the yield for the adhesive tape adhering.

In the composite adhesive tape of the present disclosure, the insulating protection layer may be positioned at a side of the first adhesive layer away from the conductive layer, or between the conductive layer and the first adhesive layer. Because the edge of the first adhesive layer has a portion protruding relative to the insulating protection layer, the adhering of the composite adhesive tape to the side edge end surface of the display unit for splicing will not be affected even if the insulating protection layer is disposed at the side of the first adhesive layer away from the conductive layer.

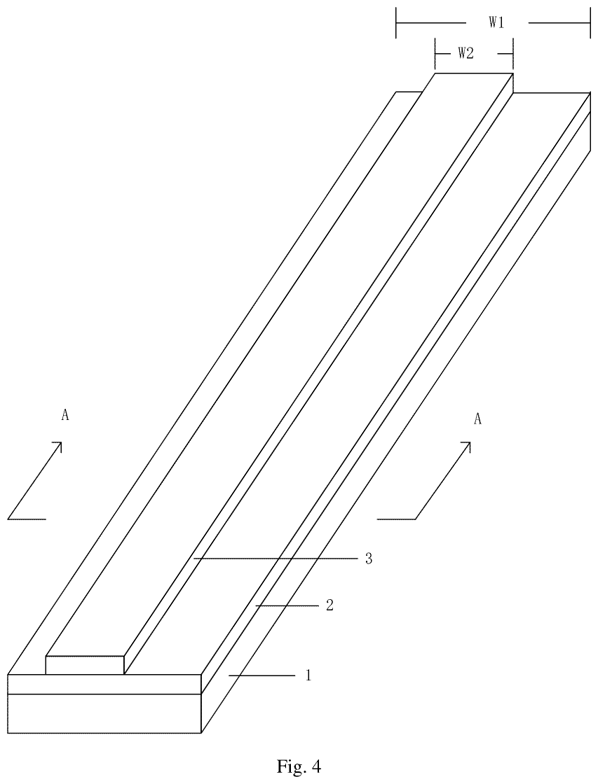

FIG. 4 shows a schematic appearance view of an embodiment of a composite adhesive tape according to the present disclosure. In this embodiment, the insulating protection layer is positioned at a side of the adhesive layer away from the conductive layer. In the figure, the composite adhesive tape is formed from a conductive layer 1, a first adhesive layer 2 and an insulating protection layer 3, wherein the conductive layer 1 and the first adhesive layer 2 have the same width W₁, and the insulating protection layer 3 has a width W2 smaller than W1. When the size of the conductive layer 1 is completely the same as that of the first adhesive layer 2, the conductive layer 1 may be completely adhered to the display device.

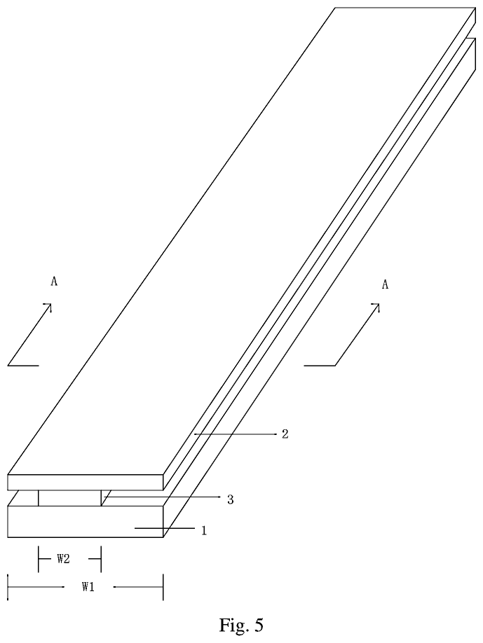

FIG. 5 shows a schematic appearance view of an embodiment of a composite adhesive tape according to the present disclosure. In this embodiment, the insulating protection layer is positioned between the conductive layer and the first adhesive layer. In the figure, the composite adhesive tape is formed from a conductive layer 1, a first adhesive layer 2 and an insulating protection layer 3, wherein the conductive layer 1 and the first adhesive layer 2 have the same width W₁, and the insulating protection layer 3 has a width W2 smaller than W1.

Although the conductive layer and the adhesive layer of the insulating protection layer 3 at the both sides in the width direction are depicted as not in contact with each other in FIG. 5 for simplicity, they may be in contact with each other in practice. Because the insulating protection layer is very thin, the conductive layer and the first adhesive layer on two sides thereof may be easily attached to each other before the operation of adhering to the display device or during the adhering operation. It is only for the purpose of making the relationship among the film layers more clear to depict as such in FIG. 5 and respective subsequent figures.

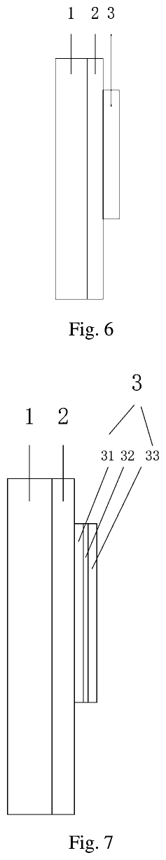

FIG. 6 shows a schematic sectional view of the embodiment of FIG. 4 in the A-A direction. In the figure, the vertical direction is the width direction of the composite adhesive tape. Here, the insulating protection layer 3 may be entirely an organic insulating film, or a stack of an organic insulating film and other film layers. Preferably, the organic insulating film is a polyimide film. In the present disclosure, the PI film sometimes serves as an example of the organic insulating film.

Preferably, the polyimide film has a thickness in a range from 0.008 mm to 0.014 mm, and more preferably has a thickness of 0.012 mm. Such thickness may have sufficient insulation function, which is beneficial for obtaining a narrow splice seam and also beneficial for the heat dissipation of the flexible circuit board.

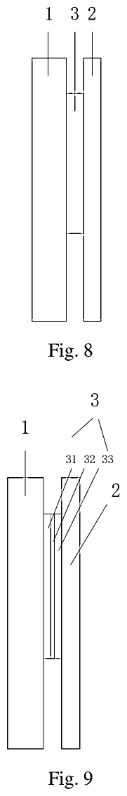

FIG. 8 shows a schematic sectional view of the embodiment of FIG. 5 in the A-A direction. The description with respect to FIG. 6 also applies to the embodiment of FIG. 8.

FIG. 7 shows a schematic diagram of an embodiment of an insulating protection layer in FIG. 6. Here, the insulating protection layer 3 may comprise an organic insulating film 31 (which may be a polyimide film) and a heat conductive layer 32. The heat conductive layer 32 is further away from the conductive layer 1 than the organic insulating film 31. As such, when the composite adhesive tape is adhered to the display device, the material of the heat conductive layer is closer to the flexible circuit board, and may have better thermal conduction function. The organic insulating film 31 may also comprise a heat conductive filler permeation region disposed within the organic insulating film 31 and at a side of the organic insulating film 31 close to the heat conductive layer 32, wherein the heat conductive filler permeation region comprises a heat conductive filler, which is the same as a material for the heat conductive layer.

The material of the heat conductive layer and/or the heat conductive filler is a material with a high thermal conductivity. Preferably, the material of the heat conductive layer and/or the heat conductive filler comprises one or more selected from the group consisting of carbon particles, silica gel and heat conductive oil. These materials may be readily compatible with the organic insulating film, and form the heat conductive layer and the heat conductive filler permeation region with a desired depth on its surface. In the heat conductive filler permeation region, the heat conductive filler may be in a state of completely or partially being embedded into the organic insulating film. The carbon particles may comprise one or more selected from the group consisting of graphite particles, diamond particles, and amorphous carbon powder particles.

Here, the graphite particles are more preferable. The graphite particles per se have good thermal conductivity, and are cheap, which is beneficial for reducing the cost of the electrically conductive adhesive tape. Graphite filler particles may permeate in the process of drying the PAA liquid film as described above. The organic insulating film with a graphite heat conductive layer on its surface has a significantly increased thermal conductivity on that surface, and may enable good heat dissipation of the flexible circuit board.

The thickness of the heat conductive layer needs to be sufficient to provide a desired thermal conduction property, and not affect the insulating property and other essential properties of the PI layer. For the heat conductive layer, a preferred thickness is in a range from 0.003 to 0.01 mm. Without being bound to any theory, it is desired to set the heat conductive layer such that for example, the IC on the flexible circuit board may be maintained in an operating temperature interval between 80° C. and 120° C., and the temperature interval belongs to a temperature interval of the integrated circuit of the flexible circuit board operating under outdoor conditions. Within the above operating temperature interval, when the thickness of the heat conductive layer is less than 0.003 mm, the thermal conductivity is insufficient; and when the thickness of the heat conductive layer is greater than 0.01 mm, the width of the splice seam is too large, resulting in the waste of the thermal conduction capacity. The thickness of the heat conductive layer may be in a range from 0.003 to 0.006 mm, such as 0.003 mm. 0.004 mm, 0.005 mm and 0.006 mm.

The thickness of the heat conductive filler permeation region, if present, is preferably less than that of the organic insulating film. Because graphite may have an electrical conduction capacity in addition to the thermal conduction capacity, the insulating effect may be affected if the thickness of the heat conductive filler permeation region is the same as that of the organic insulating film.

It should be noted that in some embodiments, the heat conductive layer may not be provided, but only the heat conductive filler permeation region is provided in the organic insulating layer at a side away from the conductive layer, and the thermal conduction effect is achieved by using the heat conductive filler permeation region.

In a particular embodiment, the insulating protection layer further comprises a light shielding film disposed at a side of the heat conductive layer away from the conductive layer. Specifically, as shown in FIG. 6, the light shielding film 33 is disposed at a side of the organic insulating film 31 away from the conductive layer 1.

In the present disclosure, a light shielding film is provided at a side of the insulating protection layer of the composite adhesive tape which will face the display unit for splicing to increase the light shielding property of the composite adhesive tape, thereby avoiding the problem of light leakage. As shown in the figure, the light shielding film 33 has a width the same as that of the organic insulating film. Although the light shielding film may be provided only in a partial region of the organic insulating film, from the viewpoint of the simplicity of preparation, the simplicity of application, and the light shielding reliability, it is desired to completely covering one side of the organic insulating film with the light shielding film. It is simple and convenient to entirely covering one side of the organic insulating film with the light shielding film in terms of design and preparation. Furthermore, this may also allow the entire surface of the organic insulating film to have light shielding property, facilitating light shielding. Larger light shielding region is also more tolerant to positional errors which may be caused by manually adhering.

The light shielding film may be preferably a black matte ink. The black matte ink may be transfer printed onto the organic insulating film with a transfer roller by transfer printing. In the present disclosure, the type of the black matte ink is not particularly limited.

Preferably, the light shielding film has a thickness in a range from 0.002 to 0.006 mm, such as a thickness of 0.004 mm. Such a thickness not only may be sufficient to shield light, but also may avoid a too large splice seam.

The conductive layer is typically a metal layer, and preferably an aluminum foil commonly used in the electronic field. The aluminum foil may provide good electrical conductivity, and provide sufficient mechanical and shape stabilities for the composite adhesive tape, while it has good adhesion to both the acrylic adhesive and the PI layer.

The composite adhesive tape may also have a release layer commonly used in an adhesive tape, facilitating storage, transport and application.

FIG. 9 shows a schematic diagram of an embodiment of an insulating protection layer in FIG. 8. The description with respect to FIG. 7 is also suitable for the embodiment of FIG. 9. Specifically, the conductive layer 1 and the insulating protection layer 3 may be configured to be in direct contact with each other. For example, the insulating protection layer 3 may be directly attached to the conductive layer 1 by means of heat treatment. When the conductive layer 1 is an aluminum foil, and the material of the insulating protection layer 3 in contact with the conductive layer 1 is PI, a good attachment effect may be obtained.

In the embodiments of FIG. 5, FIG. 8 and FIG. 9, after the first adhesive layer 2 is in direct contact with the flexible circuit board after it is adhered into the display device. Here, an anisotropic electrically conductive adhesive is selected as the first adhesive. The anisotropic electrically conductive adhesive refers to an adhesive which is electrically conductive in the Z direction, but not electrically conductive in the X and Y directions. As such, the conductive layer adhered on the light-exiting surface of the display panel by means of the first adhesive may conduct charges from the light-exiting surface, but the flexible circuit board corresponding to the bonding region will not be in communication with the conductive layer via the path formed by the first adhesive layer.

The composite adhesive tape of the present disclosure may achieve technical effects of simplifying the adhering operation, increasing the production efficiency for the splicing display panel, and increasing the yield for the adhesive tape adhering.

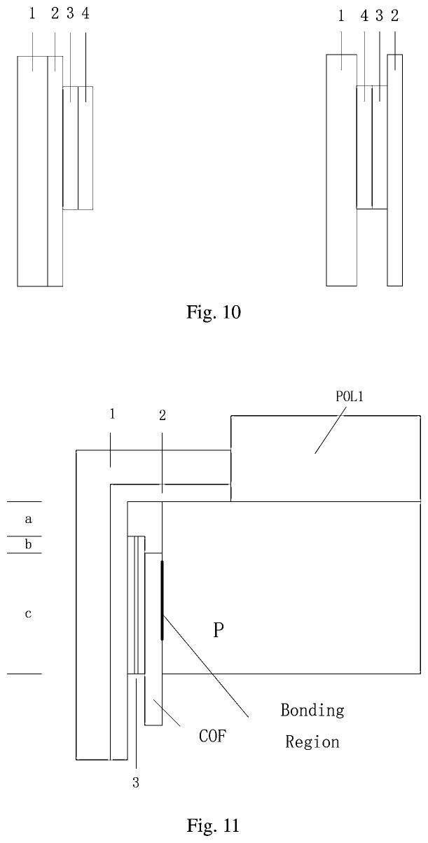

In addition to using the first adhesive layer, a second adhesive layer may be provided in the composite adhesive tape of the present disclosure. The second adhesive layer may have a width the same as that of the insulating protection layer, or may have a size completely the same as that of the insulating protection layer. The second adhesive layer is provided at a side of the insulating protection layer opposite to the first adhesive. FIG. 10 shows composite adhesive tapes where a second adhesive layer 4 is added based on the embodiments as shown in FIG. 6 and FIG. 8. The fine structures of the insulating protection layers 3 in these composite adhesive tapes may be the same as in FIG. 7 and FIG. 9. Although the use of the second adhesive layer 4 results in slightly increased thickness of the composite adhesive tape, the firmness of the composite adhesive tape is increased by providing adhesive layers on both sides of the insulating protection layer. The second adhesive layer and the first adhesive layer may be formed from the same adhesive or different adhesives, and may have the same thickness or different thicknesses.

FIG. 11 shows a flexible circuit board on a side edge end surface of a display panel P of a display device and a composite adhesive tape of the present disclosure of the type as shown in FIG. 7 adhered thereon. For simplicity, only a portion near the side edge end of the display panel P is shown. The vertical direction in the figure is its thickness direction. The upper side is the direction of its light-exiting surface, and the lower side is the direction of its back plate. The flexible circuit board is provided on its left side edge end surface. The upper end of the flexible circuit board is separated from the light-exiting surface by a distance of (a+b), and the lower end of the flexible circuit board may exceed the back plate of the display panel. A region of the flexible circuit board bonded to the bonding region needs insulation protection.

The display panel in the present disclosure may be any type of display panel, such as a liquid crystal display panel, an OLED display panel, a QD-OLED display panel, a Mini-LED panel, a Micro-LED panel and a QLED panel. The present disclosure is particularly suitable for the liquid crystal panel. Typically, the liquid crystal display panel may comprise a TFT substrate and a color film substrate arranged in a stack, a liquid crystal layer disposed between the TFT substrate and the color film, a first polarizer disposed at a side of the color film substrate away from the liquid crystal layer, a second polarizer disposed at a side of the TFT substrate away from the liquid crystal, and so on. The liquid crystal display panel may have a thickness between 0.4 mm and 0.8 mm. In FIG. 11, a liquid crystal having a first polarizer POL1 is used as an example. Of course, the present disclosure may also be used for a display panel without any polarizer.

In this embodiment, when the composite adhesive tape is adhered, the conductive layer 1 and the first adhesive layer 2 on the upper end of the composite adhesive tape bend toward the light-exiting surface of the display panel. The upper surface of the display panel below the first adhesive layer may be the upper surface of the color film substrate. That is, the composite adhesive tape forms a first portion extending along the light-exiting upper surface of the display panel, and a second portion extending along the side edge end surface. The upper end of the insulating protection layer 3 is not higher than the light-exiting surface of the display panel, or more preferably is lower than the light-exiting surface of the display panel, and does not bend toward the light-exiting surface of the display panel. This may allow the insulating protection layer not affecting the conductive layer to conduct charges away from the light-exiting surface of the display panel. Meanwhile, the upper end of the insulating protection layer 3 is higher than the upper end of the bonding region, such that the region of the flexible circuit board bonded to the bonding electrodes will be reliably protected from being in contact with the conductive layer 1.

In the figure, the edges of the conductive layer 1 and the first adhesive layer 2 are depicted as being exactly overlapped with the edge of the first polarizer POL1. This is optimal, because this not only takes full advantage of the non-display area at the frame portion such that there is sufficient contact area between the conductive layer 1 and the light-exiting surface of the display panel so as to conduct charges to the back plate, but also avoids shielding the display area where it is necessary to provide a first polarizer.

When adhering the composite adhesive tape in practice, a worker manually adheres the lower edge of the composite adhesive tape in alignment with the baseline on the back plate of the display device, then adheres the composite adhesive tape by pressing it gradually from the back side to the front side along the side edge end surface, and finally at the front surface of the display panel bends a portion of the composite adhesive tape exceeding the side edge end surface toward the display panel and adheres it. Typically, the baseline may be configured depending on the width of the composite adhesive tape and the thickness of the display device such that the bending portion of the composite adhesive tape on the upper surface of the display panel is exactly overlapped with the edge of the first polarizer. Nevertheless, there may be a slight error in practical operation. In that case, the edges of the conductive layer 1 and the first adhesive layer 2 may also not reach or may exceed the edge of the first polarizer. In the present disclosure, the morphology where the edges of the conductive layer 1 and the first adhesive layer 2 exceed the edge of the first polarizer and are adhered to the upper surface of the first polarizer is called “lapping”. That is, the conductive layer may be lapped on the upper surface of the first polarizer, or may not be lapped on the upper surface of the first polarizer. The basic electrical conduction function may still be achieved, as long as the error is not so large that the conductive layer 1 and the first adhesive layer 2 cannot bend to the light-exiting surface of the display panel. The bending first portion should be as large as possible as long as it does not affect the display, but the bending first portion should not cover the display area of the display panel. The bending portion is also beneficial for avoiding the glue failure at the edge of the front surface of the display panel under high temperature and high humidity conditions of the reliability test.

If what is to be used is not a display panel with a first polarizer, the baseline may be set depending on the widths of the display area of the display panel and the non-display area at the frame.

Preferably, the insulating protection layer should not comprise a portion capable of being bent to the light-exiting surface of the display panel, so as to avoid the influence on the electrical conduction from the light-exiting upper surface of the display panel. For the liquid crystal display panel, the first polarizer layer typically has a thickness in a range from 0.15 to 0.3 mm, and typically exhibits retraction at the edge relative to the side edge end surface of the color film substrate by a distance in a range from 0.25 to 0.8 mm. The edge of the first polarizer is typically not the boundary between the display area and the non-display area, but disposed in the non-display area. A black matrix may be provided at the frame to confine the display area. The edge of the display area (i.e., its boundary with the non-display area) exhibits retraction relative to the side edge end surface of the color film substrate by a distance typically slightly greater than the first polarizer, for example a distance in a range from 0.5 to 1.0 mm. The distance of the bending portion may be configured to be less than the distance of the retraction of the edge of the display area, so as to avoid entering into the display area to affect the display. Preferably, the distance of the bending portion may be greater than or equal to the distance of the retraction of the first polarizer, so as to be in sufficient contact with the upper surface. From the viewpoint of simple design, it may be designed that the distance of the bending portion is equal to the distance of the retraction of the first polarizer. The distance of the bending portion may also be less than the distance of the retraction of the first polarizer. However, in view of ensuring the electrical conductivity, the minimum distance should not be set to be less than 0.2 mm.

After adhering, the higher the upper edge of the insulating protection layer, the better the insulation protection effect on the flexible circuit board is. However, if the upper edge of the insulating protection layer is too high and is close to the upper surface of the display panel, it is more likely to bend to the upper surface in practical adhering. Therefore, a distance should be remained between the upper edge of the insulating protection layer on the side edge end surface and the upper surface of the display panel, so as to prevent the insulating protection layer from bending to the upper surface of the display panel along with the conductive layer. This distance is at least 0 mm, and preferably 0.2 mm or more. Because the upper edge of the insulating protection layer must at least be higher than the upper edge of the flexible circuit board, and a distance should be remained between the upper edge of the insulating protection layer and the upper edge of the flexible circuit board to ensure the insulation protection on the flexible circuit board, the distance between the upper edge of the insulating protection layer and the upper surface of the display panel should not be too large. After adhering, the distance between the upper edge of the insulating protection layer and the upper edge of the flexible circuit board (for example, the distance b as shown in FIG. 11) is at least 0.1 mm, and preferably greater than or equal to 0.2 mm, for example 0.3 mm. For example, the upper edge of the insulating protection layer may be appropriately disposed substantially in the middle of the distance between the flexible circuit board and the light-exiting upper surface (the upper surface of the color film substrate), such that the upper edge of the insulating protection layer maintains sufficient distances from both the light-exiting upper surface and the upper edge of the flexible circuit board. The distance between the flexible circuit board and the light-exiting upper surface may be in a range from 0.3 to 0.65 mm. It is typically 0.4 mm. For a distance of 0.4 mm, the upper edge of the insulating protection layer may be configured to be separated from the light-exiting upper surface by a distance of 0.2 mm and separated from the upper edge of the flexible circuit board by a distance of 0.2 mm after adhering. It should be noted that in particular implementations, the upper edge of the insulating protection layer may also bend close to the side edge end surface after adhering. In this case, the distance between the upper edge of the insulating protection layer and the upper edge of the flexible circuit board after adhering refers to the length of the curved path of the insulating protection layer between the upper edge of the insulating protection layer and the upper edge of the flexible circuit board (which may be understood as a length extending from the upper edge of the insulating protection layer to the upper edge of the flexible circuit board along a surface of the insulating protection layer close to the flexible circuit board).

For the composite adhesive tape, the total retraction of the edge of the insulating protection layer relative to the edge of the conductive layer is substantially equal to a sum of the distance of the bending first portion and the distance between the upper edge of the insulating protection layer and the light-exiting upper surface. In an embodiment, the total retraction of the edge of the insulating protection layer relative to the edge of the conductive layer should at least ensure the distance of the bending first portion of 0.2 mm. In the case where the display area is farthest from the side edge end surface and also the flexible circuit board is farthest from the upper surface (about 1.0 mm+0.65 mm), the maximum retraction of the insulating protection layer may be 1.4 mm, ensuring that the distance between the edge of the insulating protection layer and the upper edge of the flexible circuit board is 0.2 mm or more and a distance of 0.05 mm is remained between the conductive layer and the display area so as to prevent the influence on the display. The composite adhesive tape in which the total distance of the retraction of the edge of the insulating protection layer relative to the edge of the conductive layer is in a range from 0.2 mm to 1.4 mm may be suitable for most display devices.

On this basis, a proper baseline position is set on the display device for alignment by workers when the composite adhesive tape is adhered. The retraction distance of the insulating protection layer in the composite adhesive tape may be appropriately designed depending on the particular position of the upper end of the flexible circuit board and the particular size of the frame region of the display panel, taking good insulating property, good electrical conductivity, small influence on the display and sufficient tolerance of error in manual adhering into account.

As compared to the adhering process in the related art as shown in FIG. 1 or FIG. 2, the electrical conduction and insulation functions are integrated in the composite adhesive tape of the present disclosure. Therefore, for each side edge end surface of the display panel, workers need to perform the adhering operation of the adhesive tape only once, rather than adhering twice in the related art. For one display panel, the adhering operation needs to be performed only 4 times, rather than 8 times in the related art. This significantly reduces the amount of the labor of the workers, increasing the production efficiency and reducing the production working hours.

Also, the present disclosure provides a simple process for ensuring the proper position of the insulating protection layer for workers by appropriately designing the retraction amount of the insulating protection layer.

Preferably, the width of the insulating protection layer is greater than or equal to 1.6 mm. The insulating protection layer needs to sufficiently cover the region of the flexible circuit board bonded to the bonding electrodes, especially when the bonding region is configured as the aforementioned first configuration. In this regard, as shown in FIG. 11, the width c of the flexible circuit board covered by the insulating protection layer is greater than or equal to 1.5 mm. Therefore, the total width b+c of the insulating protection layer is greater than or equal to 1.6 mm. More ideally, the total width b+c of the insulating protection layer is greater than or equal to 1.7 mm. When a PI film is used as the organic insulating film, in view of the cost of the PI film, too large width of the PI film is not necessary. Thus, preferably, the width of the insulating protection layer is less than or equal to 5 mm. A width of 5 mm may generally meet various requirements.

FIG. 11 does not show particular adhering situation of the lower end of the composite adhesive tape to the display device. The conductive layer and the first adhesive layer may bend to a side of the back plate body away from the display panel, or may be adhered to the flanging of the back plate when the back plate has a flanging. Both may achieve a grounded conductive path.

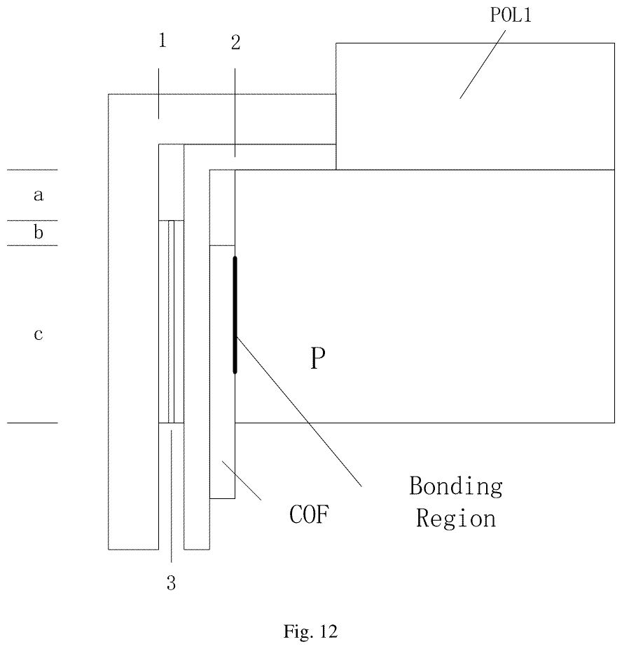

FIG. 12 shows a schematic structural diagram of a side edge end surface of a display panel in another embodiment of a display device according to the present disclosure. The figure shows a flexible circuit board on the side edge end surface of the display panel P of the display device and the composite adhesive tape of the present disclosure as shown in FIG. 8 adhered thereon. The description with respect to FIG. 11 is also suitable for the embodiment of FIG. 12. The first adhesive layer in this embodiment is an anisotropic electrically conductive adhesive, which is electrically conductive in its thickness direction, but not electrically conductive in its extending direction. Therefore, although there is a path of first adhesive layer between the conductive layer and the flexible circuit board, this will not result in electrical conduction therebetween.

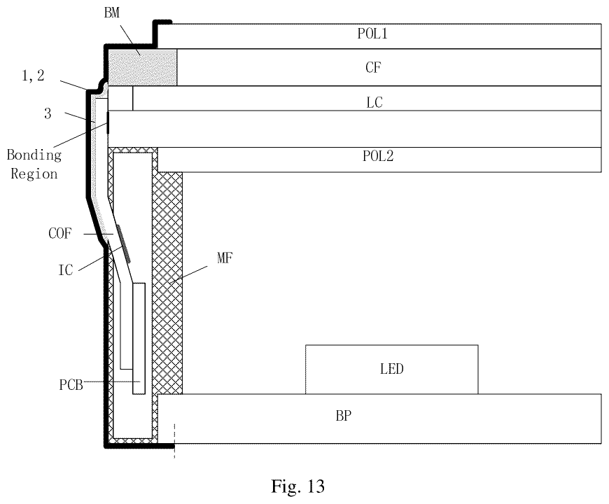

FIG. 13 shows a schematic diagram of an embodiment of a display device according to the present disclosure where the composite adhesive tape has been adhered to the display device of FIG. 1. In the figure, for simplicity, the conductive layer 1 and the first adhesive layer 2 which are completely overlapped with each other are shown together. As can be seen from the figure, the insulating protection layer 3 covers the region of the flexible circuit board bonded to the bonding electrodes, ensuring that it will not be electrically conductive with the conductive layer, and heat may be sufficiently dissipated from the flexible circuit board. The conductive layer is connected to the light-exiting surface of the display panel and the back plate of the display device, and serves for conducting the accumulated electrostatic charges or charge surge away. Generally, a sum of the width of the non-display area around the display area of the display panel and the thickness of the flexible circuit board may be in a range from 0.5 mm to 1.0 mm. When the composite adhesive tape with a properly designed size is used, workers may conveniently control the distance of the bending first portion to not affect the display area by adhering the lower edge of the composite adhesive tape to the baseline (the dash line). Practical baseline may be marked on the back plate for workers to achieve alignment. In FIG. 13, the composite adhesive tape of the type as shown in FIG. 6 is used. It may be appreciated that the adhering for the composite adhesive tape of the type as shown in FIG. 7 may be performed in the same manner.

With respect to the existing adhesive tape in the related art, the composite adhesive tape of the present disclosure may at least partially solve the technical problems of: difficulty in further reducing the splice seam width; low product production efficiency, low productivity of the production line; complex product production operation, defects such as bright lines displayed due to the short circuit of the drive flexible circuit board caused by inaccurate manually adhering position of the elastic adhesive tape; glue failure of the adhesive tapes in a high temperature and high humidity reliability test, causing light leakage and short circuit of the product; low heat dissipation efficiency of the drive flexible circuit board, causing abnormal picture in a high temperature reliability test or at too high temperature.

The following technical effects may be achieved by using the composite adhesive tape of the present disclosure: high heat dissipation efficiency, avoiding abnormal picture caused in a high temperature reliability test or at too high temperature; further reduced splice seam width; reduced numbers of adhering operations, increasing production efficiency and reducing production hours; fixed relative positions of the conductive layer and the insulating protection layer, achieving the electrical conduction function while ensuring the insulation function, thereby avoiding inaccurate position occurred when manually adhering; good chemical stability and heat and humidity resistance of the PI film, reducing light leakage and short circuit due to glue failure of the product in a high temperature and high humidity reliability test, and cooperating with a light shielding film to further reduce light leakage.

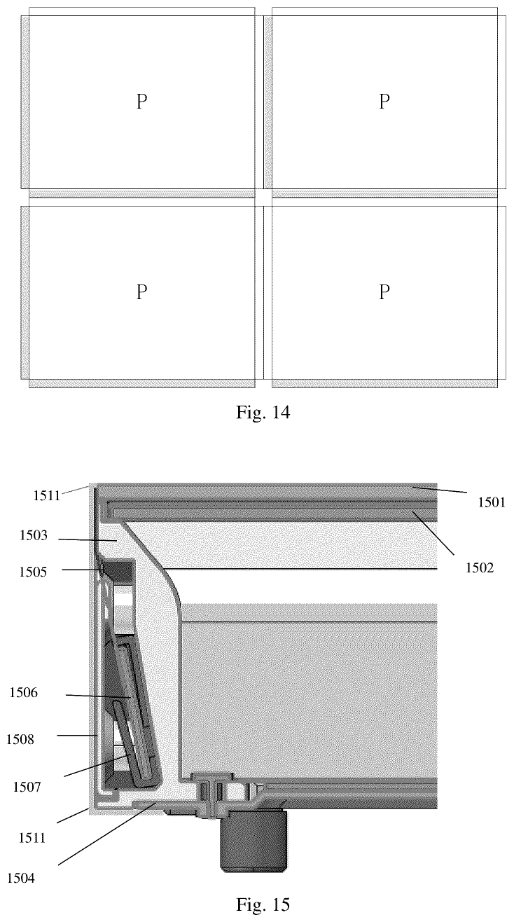

The above composite adhesive tape is designed for a side edge end surface having a bonding region and a flexible circuit board, while a conventional electrically conductive adhesive tape is sufficient to form a conductive path between the front surface and the back surface for other side edge end surfaces. Nevertheless, in production, if the worker change the adhesive tapes frequently, it is likely to cause confusion. Therefore, for the purpose of simple and efficient operation, the composite adhesive tape may also be used on a side edge end surface having no bonding region or flexible circuit board. For example, industrially, the display panel generally has a bonding region and a flexible circuit board on the bottom side and the left side, but has no bonding region or flexible circuit board on the top side and the right side. When a plurality of display devices comprising such a display panel are spliced together, the composite adhesive tape of the present disclosure may be used on the bottom side and the left side of each display panel, and a conventional electrically conductive adhesive tape may be used on the left side and the right side. As shown in FIG. 14, grey color represents the composite adhesive tape of the present disclosure, and white color represents the conventional electrically conductive adhesive tape. The conventional electrically conductive adhesive tape is thinner because of having no insulating protection layer, and may achieve a narrower splice seam. Nevertheless, as described above, for the purpose of simple and efficient operation, all conventional electrically conductive adhesive tapes may be replaced with the composite adhesive tape of the present disclosure. As such, in production, workers need not change the adhesive tape frequently, and only need to use a single kind of adhesive tape.

As compared to the aforementioned splice seam width of 1.54 mm in the related art, for a display panel having the same black matrix width and connected to the same flexible circuit board, the adhesive tape of the present disclosure may achieve a smaller splice seam width. Specifically, the insulating protection layer of the present disclosure requires lower strength and may be thinner because it is integrated into the composite adhesive tape. For example, as compared to a conventional insulating elastic adhesive tape of 0.05 mm, the insulating protection layer only has a thickness of 0.021 mm. Therefore, the total splice seam thickness may be reduced by about 0.06 mm, down to 1.5 mm or less.

As shown in FIG. 14, after the composite adhesive tape is adhered on all the four sides of each display device P, the display devices P are spliced with the light-exiting surfaces disposed in the same plane, thereby achieving a display apparatus having a display area four times greater than the display device.

Some perforations may be provided at appropriate positions on the composite adhesive tape in advance. For example, the perforations for screws to pass through are provided in advance at positions on the composite adhesive tape corresponding to positions where screws are required for fixation on the side edge end surface of the display device.

A display device having a specific structure may be obtained by using the above composite adhesive tape. The display device has an insulating protection layer provided for the region of the flexible circuit board bonded to the bonding electrodes, wherein the insulating protection layer comprises an organic insulating film, and the organic insulating film comprises a heat conductive layer on a surface close to the flexible circuit board. The organic insulating film having a heat conductive layer at one side may help the flexible circuit board dissipate heat well while performing the insulation function.

It may be appreciated that the above composite adhesive tape may also be used for writing pads, touch pads or other electronic products, which is beneficial for achieving narrow frame configuration for the interactive interface of electronic products and improving the interactive experience of users.

In an embodiment, a display device is provided, the display device comprising:
a display panel having a light-exiting upper surface, a lower surface opposite to the light-exiting upper surface and a plurality of side edge end surfaces between the light-exiting upper surface and the lower surface, wherein the display panel comprises a first group of bonding electrodes at a side where a first side edge end surface in the plurality of side edge end surfaces is located;
a first flexible circuit board electrically connected to the first group of bonding electrodes, wherein an upper edge of the first flexible circuit board is lower than an upper edge of the first side edge end surface;
a first insulating protection layer at a side of the first flexible circuit board away from the first group of bonding electrodes, wherein an upper edge of the first insulating protection layer is higher than the upper edge of the first flexible circuit board, and a lower edge of the first insulating protection layer is lower than the first group of bonding electrodes;
a first conductive layer comprising a first portion extending along the light-exiting upper surface of the display panel and a second portion extending along the first side edge end surface, wherein the first insulating protection layer is between the second portion and the first flexible circuit board; and
a first adhesive layer at a side of the first conductive layer close to the display panel, wherein the first insulating protection layer is between the first adhesive layer and the first flexible circuit board or between the first adhesive layer and the first conductive layer.

In the display device, the first side edge end surface of the display panel with the first flexible circuit board mounted thereto is covered by the first conductive layer, the first insulating protection layer and the first adhesive layer. The display panel has a plurality of side edge end surfaces between the light-exiting upper surface and the opposite lower surface. For example, a rectangular display panel has four side edge end surfaces. At least one of the side edge end surfaces has a bonding region. The first group of bonding electrodes on the first side edge end surface are investigated. The first flexible circuit board is electrically connected to the first group of bonding electrodes. Thus, at least a portion of the first flexible circuit board extends on the first side edge end surface and an orthographic projection thereof on the first side edge end surface covers the first group of bonding electrodes. The other portion of the first flexible circuit board may, for example, extend toward the cavity in the intermediate frame, and may be connected to a drive circuit board. An upper edge of the first flexible circuit board is lower than an upper edge of the first side edge end surface, i.e., an edge of the light-exiting upper surface. The outermost first conductive layer is used to conduct accumulated electrostatic charges or charge surge on the front surface of the display panel to the back surface of the display device, performing the function of electrical protection. Therefore, it comprises a first portion extending along the light-exiting upper surface of the display panel. It further comprises a second portion extending along the first side edge end surface. It may further comprise a third portion extending along a surface of the back plate opposite to the display panel. In some particular embodiments, the first conductive layer may comprise only the second portion. In some particular embodiments, if sufficient electrical conduction capability can be provided, the first portion and/or the third portion may also be omitted or replaced by another structure. The first insulating protection layer needs to protect the first flexible circuit board from leaking current to the first conductive layer, so it is disposed between the first conductive layer and the first flexible circuit board, its upper edge must be higher than the upper edge of the flexible circuit board, and its lower edge must be lower than the lower edge of the first group of bonding electrodes, achieving the complete coverage of the region of the flexible circuit board corresponding to the bonding region. The first adhesive layer is used to adhere the first conductive layer and the first insulating protection layer to the side edge end surface of the display panel. It may be disposed between the first flexible circuit board and the first insulating protection layer, or between the first insulating protection layer and the first conductive layer. The first adhesive layer is disposed at a side of the first conductive layer close to the display panel, and is completely overlapped with the first conductive layer, to ensure that the first conductive layer is completely adhered to the display panel.

Specifically, the display device may comprise a display panel, an intermediate frame and a back plate. The intermediate frame is used for supporting the display panel. The back plate comprises a back plate body at a side of the intermediate frame away from the display panel. In some embodiments, the back plate further comprises a back plate flanging, which may be configured to extend toward the display panel at the edge of the back plate in a direction perpendicular to the back plate body. The display device may further comprise a backlight source disposed between the back plate body and the display panel. The backlight source may be, for example, an edge-lit backlight source or a direct-lit backlight source. Specifically, a light source film layer is further provided between the backlight source and the display panel. The light source film layer may function to homogenize light emitted by the backlight source.

The first conductive layer may be configured to be electrically connected to the front surface of the display panel of the display device and the back plate of the display device respectively to ground the display panel. The first conductive layer may be in direct contact with the back plate to form an electrical connection, or may be electrically connected to the back plate via an electrically conductive adhesive.

In the thickness direction of the side edge end surface of the display panel, the first conductive layer extends a distance such as to ensure that it may be connected to the back plate. The entire width of the first conductive layer may be greater than the thickness of the edge of the display device. Specifically, the first conductive layer may bend toward a side of the back plate body away from the display panel (i.e., the back surface of the back plate) and be adhered thereon. In this way, a conductive path from the front surface of the display panel to the back plate may be formed, and it is ensured that external charges in contact with the front surface of the display panel may rapidly flow back to the back plate (which may be regarded as grounded). When the display panel is in the cases of electrostatic charge accumulation or external charge surge, the circuit of the display panel itself will not be affected or damaged, ensuring normal display. If the back plate has a back plate flanging, the first conductive layer may also not bend toward the side of the back plate body away from the display panel, and may be directly adhered to the flanging. In sum, the first conductive layer is used to conduct charges on the front surface of the display device as the display unit for splicing to the back surface.

Specifically, the first conductive layer may be adhered to the display device via a first adhesive layer, wherein the first adhesive layer comprises an electrically conductive adhesive. For example, the first adhesive layer is an acrylic adhesive layer.

On the front surface of the display panel, the first conductive layer may bend from the side edge end surface of the display panel toward its light-exiting surface and extends at the edge of the display panel along a direction in parallel to the plane where the light-exiting surface of the display panel is located (for example, the surface of the color film substrate or the polarizer) to direct out charges on the light-exiting surface of the display panel. The bending width of the first conductive layer preferably does not enter into the display area of the display panel.

Typically, the total width of the first conductive layer from its upper end to its lower end may be in a range from 25 to 45 mm, such as 35 mm. Such a width is suitable for a current conventional display device.

In a particular embodiment, the conductive layer is preferably an aluminum foil. Various conventional aluminum foils in the field of electronic device may be used. A typical thickness of the aluminum foil is in a range from 0.03 to 0.04 mm, such as 0.036 mm.

In a particular embodiment, the first adhesive layer is a layer at least to provide adhesion for the first conductive layer, such that the first conductive layer may be adhered to the side edge end surface of the display device and the light-exiting surface of the display panel. The first adhesive layer is disposed at a side of the first conductive layer, and has a width the same as that of the first conductive layer. In other words, the first adhesive layer is completely overlapped with the first conductive layer. As such, it may be ensured that the entire first conductive layer is firmly adhered. The first adhesive layer also has an electrical conductivity in its thickness direction, enabling electrical conduction between the first conductive layer adhered thereby and the surface being adhered.

In a particular embodiment, a common pressure-sensitive adhesive may be used as the first adhesive. Typically, a conventional adhesive in an electrically conductive aluminum foil in the related art is used. An example of the pressure-sensitive adhesive is an acrylic adhesive. A typical thickness of the first adhesive layer is in a range from 0.012 to 0.016 mm, such as 0.014 mm.

In a particular embodiment, a sum of the thicknesses of the first conductive layer and the first adhesive layer may be, for example, 0.05 mm.

In a particular embodiment, the insulating protection layer comprises an organic insulating film which comprises an organic insulating film, and a heat conductive layer disposed at a side of the organic insulating film away from the conductive layer. Preferably, the organic insulating film comprises a heat conductive filler permeation region disposed within the organic insulating film and at a side of the organic insulating film close to the heat conductive layer; wherein the heat conductive filler permeation region comprises a heat conductive filler, which is the same as a material for the heat conductive layer. There is no need to separately adhere a heat conductive adhesive to each flexible circuit board by providing the heat conductive layer and the heat conductive filler permeation region in the insulating protection layer. The organic insulating film may achieve the permeation of the carburized filler more easily, and may be prepared in the form of adhesive tape to facilitate the mounting operation. Therefore, the mounting of the heat conductive film layer may be achieved while providing the organic insulating film on the side edge end surface of the display device. As compared to the display device prepared by providing a plurality of heat conductive adhesives and then providing an insulating film layer in the related art, the preparation of the display device of the present disclosure may achieve the thermal conduction and electrical insulation functions in a single operation, which greatly simplifies the preparation method.

In an embodiment, the heat conductive layer and the heat conductive filler permeation region may be formed by treating a surface of the organic insulating film with a heat conductive filler. The surface treatment comprises treating with a heat conductive filler after the organic insulating film is formed or before the precursor of the organic insulating film is converted into the organic insulating film. For example, for polyimide (PI), after forming a PI film, a heat conductive filler may be stamped onto the surface of the PI film by hot stamping, thereby forming a heat conductive layer and a heat conductive filler permeation region. The heat conductive filler may also permeate to form the heat conductive layer and the heat conductive filler permeation region before preparing PI from polyamic acid (PAA). Typically, the PI film is prepared by steps of: preparing a PAA solution by polymerizing a dianhydride and a diamine in a solvent; casting the PAA solution to form a PAA liquid film; drying the PAA liquid film to form a PAA solid film; orientation stretching the PAA solid film into a strip-shaped PAA film; and dehydrating and catalyzing the strip-shaped PAA film to form a strip-shaped PI film. In this process, particles of the heat conductive filler may be provided to the surface of the PAA film in the process of drying the PAA liquid film into the PAA solid film, and thus the final strip-shaped PI film may have a heat conductive filler permeation region and a heat conductive layer on its surface. The particles of the heat conductive filler may be carbon particles, such as graphite particles, diamond particles, etc. Among them, graphite particles are preferable due to its high thermal conductivity and low cost.

The material of the heat conductive layer and/or the heat conductive filler is a material with a high thermal conductivity. Preferably, the material of the heat conductive layer and/or the heat conductive filler comprises one or more selected from the group consisting of carbon particles, silica gel and heat conductive oil. These materials may be readily compatible with the organic insulating film, and form the heat conductive layer and the heat conductive filler permeation region with a desired depth on its surface. In the heat conductive filler permeation region, the heat conductive filler may be in a state of being embedded into the organic insulating film. The carbon particles may comprise one or more selected from the group consisting of graphite particles, diamond particles, and amorphous carbon powder particles.

Here, the graphite particles are more preferable. The graphite particles per se have good thermal conductivity, and are cheap, which is beneficial for reducing the cost of the electrically conductive adhesive tape. Graphite filler particles may permeate in the process of drying the PAA liquid film as described above. The organic insulating film with a graphite heat conductive layer and graphite particle permeation layer on its surface has a significantly increased thermal conductivity and stability on that surface, and may enable good heat dissipation of the flexible circuit board.

The thickness of the heat conductive layer needs to be sufficient to provide a desired thermal conduction property, and not affect the insulating property and other essential properties of the PI layer. For the heat conductive layer, a preferred thickness is in a range from 0.003 to 0.01 mm. Without being bound to any theory, it is suitable to configure the heat conductive layer and the heat conductive filler permeation region such that for example, the IC on the flexible circuit board may be maintained in an operating temperature interval between 80° C. and 120° C., and the temperature interval belongs to a temperature interval of the integrated circuit of the flexible circuit board operating under outdoor conditions. Within the above operating temperature interval, when the thickness of the heat conductive layer is less than 0.003 mm, the thermal conductivity is insufficient; and when the thickness of the heat conductive layer is greater than 0.01 mm, the width of the splice seam is too large, resulting in the waste of the thermal conduction capacity. The thickness of the heat conductive layer may be in a range from 0.003 to 0.006 mm, such as 0.003 mm, 0.004 mm, 0.005 mm and 0.006 mm.

The thickness of the heat conductive filler permeation region, if present, is preferably less than that of the organic insulating film. Because graphite may have an electrical conduction capacity in addition to the thermal conduction capacity, the insulating effect may be affected if the thickness of the heat conductive filler permeation region is the same as that of the organic insulating film.

It should be noted that in some embodiments, the heat conductive layer may not be provided, but only the heat conductive filler permeation region is provided in the organic insulating layer at a side close to the flexible circuit board, and the thermal conduction effect is achieved by using the heat conductive filler permeation region.

In a particular embodiment, the first insulating protection layer is disposed at a side of the first conductive layer, and in the width direction in which the first conductive layer extends, and edges at both ends of the first insulating protection layer exhibit retraction respectively relative to edges at both ends of the first conductive layer. A side edge of the first insulating protection layer close to the light-exiting surface of the display panel exhibits retraction toward the back plate body relative to the corresponding side edge of the first conductive layer, thereby ensuring that the electrical conduction between the first conductive layer and the light-exiting surface of the display panel will not be impeded. A side edge of the first insulating protection layer close to the back plate body exhibits retraction toward the light-exiting surface of the display panel relative to the corresponding side edge of the first conductive layer, thereby ensuring that the electrical conduction between the conductive layer and the back plate will not be impeded. In a particular embodiment of the present disclosure, a first insulating protection layer comprising a heat conductive layer and a heat conductive filler permeation region and having particular width and positional design may provide reliable protection, which may be easily achieved manually, for the position (for example, a bonding region) on the side edge end surface of the display device for bonding the first flexible circuit board to the display panel, avoiding the risk of the contact between the first flexible circuit board and the first conductive layer during adhering and the risk of the insulation of the first conductive layer from the display panel. Meanwhile, this structure also provides good heat dissipation for the first flexible circuit board. Besides, the structure of the present invention may also function to mechanically reinforce the bonding of the first flexible circuit board to the bonding electrodes. The aforementioned reinforcing adhesive layer process may be omitted by using the structure of the present invention, thereby saving the cost. Preferably, there is no need to use the aforementioned reinforcing adhesive layer.

In this embodiment, various film layers may have the same features and achieve the same advantageous effects as in the above composite adhesive tape.

In a particular embodiment, the organic insulating film may be a polyimide (PI) film or a polyethylene terephthalate (PET) film. In an embodiment, a material for the organic insulating film comprises polyimide. As described previously, it has better insulating property and thermal deformation resistance.

In an embodiment, the organic insulating film has a thickness in a range from 0.008 mm to 0.014 mm. The use of the display device for splicing is beneficial for obtaining a narrow splice seam and also beneficial for the heat dissipation of the flexible circuit board. For example, the organic insulating film has a thickness of 0.012 mm.

Preferably, the first insulating protection layer further comprises a light shielding film disposed at a side of the heat conductive layer away from the conductive layer. The light shielding film is beneficial for preventing light leakage. The light shielding film may also be provided at another position, for example, at a side of the organic insulating film close to the conductive layer, at a side of the heat conductive layer close to the conductive layer, or on both sides of the conductive layer. Nevertheless, in these positions, the light shielding film is closest to the display unit when it is located on the side of the heat conductive layer away from the conductive layer, such that better light leakage resistance may be provided. The light shielding film may also be provided on the display panel or on the flexible circuit board, but the process will be more complex than the case where it is provided on the first insulating protection layer.

Preferably, the light shielding film is a black matte ink. It may be provided on the organic insulating layer by transfer printing, and may achieve good light shielding property at a small thickness.

Preferably, the light shielding film has a thickness in a range from 0.002 to 0.006 mm. This may avoid too large splice seam.

Preferably, a material of the first conductive layer comprises aluminum. It is highly cost effective. The first conductive layer may be disposed to be in direct contact with the first insulating protection layer.

Preferably, a total width of the first conductive layer between the upper edge of the first insulating protection layer and an upper end of the conductive layer is in a range from 0.2 mm to 1.4 mm. The upper end of the conductive layer refers to the end of the conductive layer. For example, when the conductive layer serves as a portion of the composite adhesive tape, the upper end of the conductive layer corresponds to the edge of the composite adhesive tape. As described above, this ensures that the conductive layer may be adhered to the front surface of the display panel for electrical conduction, while the flexible circuit board can be well protected.

Preferably, the distance between the upper edge of the first insulating protection layer and the upper edge of the first flexible circuit board is 0.1 mm or more. Preferably, the distance is greater than or equal to 0.2 mm, for example 0.3 mm. It should be noted that in particular implementations, the upper edge of the insulating protection layer may also bend close to the side edge end surface after adhering. In this case, the distance between the upper edge of the insulating protection layer and the upper edge of the flexible circuit board after adhering refers to the length of the curved path of the insulating protection layer between the upper edge of the insulating protection layer and the upper edge of the flexible circuit board (which may be understood as a length extending from the upper edge of the insulating protection layer to the upper edge of the flexible circuit board along a surface of the insulating protection layer close to the flexible circuit board). As described above, this may ensure that the insulating protection layer well protects the upper edge of the flexible circuit board.

Preferably, the distance between the upper edge and the lower edge of the insulating protection layer is in a range from 1.6 to 5 mm. More ideally, the distance between the upper edge and the lower edge of the insulating protection layer is in a range from 1.7 to 5 mm. As described above, this is beneficial for sufficiently protect the region of the flexible circuit board bonded to the bonding electrodes, while avoiding too high cost.

In an embodiment, the display device further comprises:
a back plate and a supporting intermediate frame disposed between the display panel and the back plate;
wherein the first conductive layer is electrically connected to the back plate.

The first conductive layer may be in direct contact with the back plate to form an electrical connection, or may be electrically connected to the back plate via an electrically conductive adhesive. The first conductive layer may be mounted to the back plate with a mounting structure (such as a screw) to form a direct contact electrical connection.

FIG. 15 shows a schematic structural diagram of an embodiment of a display device according to the present disclosure. Here, the top is a liquid crystal display panel 1501, which particularly comprises film layers such as an array substrate, a liquid crystal layer, a color film substrate, an upper polarizer and a lower polarizer. An optical film layer 1502 is disposed between the liquid crystal display panel and a backlight module to function to adjust the backlight. The liquid crystal display panel 1501 is supported by an intermediate frame 1503, and the intermediate frame 1503 is further supported on the back plate 1504 of the display device. A backlight module such as a LED backlight module may be provided on the back plate 1504. The backlight module outputs light upwards, and the light passes through the optical film layer 1502 and the liquid crystal display panel 1501 to achieve the display. A flexible circuit board 1505 is provided at an end of the liquid crystal display panel, extends downwards along the left end of the liquid crystal display panel, and then extends toward the lower right into the cavity in the intermediate frame 1503. A printed circuit board PCB 1506 is provided in the cavity. The printed circuit board is housed in a PCB holder 1507, and protected on the outside by a PCB protection cover 1508. A composite adhesive tape 1511 is adhered on the left end of the display device with its upper end aligned with the light-exiting surface of the liquid crystal display panel 1501, and is adhered to the side edge end surface of the liquid crystal display panel 1501, the flexible circuit board 1505, the intermediate frame 1503, the PCB protection cover 1508 and the intermediate frame 1503 in this order from top to bottom, and then bend to the right at the bottom to be adhered to the back plate 1504.

In an embodiment, the display panel has a rectangular outer contour and has 4 side edges comprising a first side edge having the first side edge end surface, and the display panel further comprises a second side edge having a second side edge end surface and a second group of bonding electrodes at a side where the second side edge end surface is located, wherein the second side edge is adjacent to the first side edge;
wherein the display device comprises a second flexible circuit board electrically connected to the second group of bonding electrodes, wherein an upper edge of the second flexible circuit board is lower than an upper edge of the second side edge end surface;
a second insulating protection layer at a side of the second flexible circuit board away from the second group of bonding electrodes, wherein an upper edge of the second insulating protection layer is higher than the upper edge of the second flexible circuit board, and a lower edge of the second insulating protection layer is lower than the second group of bonding electrodes;
a second conductive layer comprising a first portion extending along the light-exiting upper surface of the display panel and a second portion extending along the second side edge end surface, wherein the second insulating protection layer is between the second portion of the second conductive layer and the second flexible circuit board; and
a third adhesive layer at a side of the second conductive layer close to the display panel, wherein the second insulating protection layer is between the third adhesive layer and the second flexible circuit board or between the third adhesive layer and the second conductive layer;
wherein the display panel comprises a data line extending along the second side edge and a gate line extending along the first side edge, wherein the data line is connected to the first group of bonding electrodes, and the gate line is connected to the second group of bonding electrodes.

The rectangular display panel may have two adjacent edges each with a flexible circuit board. In this case, both edges may have the structure of the present disclosure or use the composite adhesive tape of the present disclosure. Typically, those two edges are the lower edge and the left edge when viewing the conventional display panel from the front. They may be used for the data line and the gate line, respectively. As described previously, for the convenience of increasing the operation efficiency of workers, an edge having no flexible circuit board may also use the composite adhesive tape of the present disclosure. For example, the composite adhesive tape of the present disclosure is adhered on all four end surfaces of the rectangular display panel.

In an embodiment, the present disclosure also provides a display apparatus, wherein the display apparatus is formed by splicing a plurality of display devices according to the present disclosure, and light-exiting upper surfaces of the plurality of display devices are in the same plane. A part thereof may be as schematically shown in FIG. 14.

In an embodiment, the present disclosure also provides a display unit for splicing comprising a display device having at least one edge with the composite adhesive tape of the present disclosure adhered. In a particular embodiment, the composite adhesive tape of the present disclosure is adhered on all four edges of the display unit to further increase the operation efficiency of workers.

### Example 1

A composite adhesive tape as shown in FIG. 6 was prepared by the following steps.

(1) An aluminum foil with a thickness of 0.036 mm was prepared. The aluminum foil was die cut into a strip with a width of 35 mm.

(2) An electrically conductive acrylic adhesive layer with a thickness of 0.014 mm was applied on the aluminum foil. The acrylic adhesive layer was completely overlapped with the aluminum foil.

(3) A solution of PAA was cast on a flat plate to form a PAA liquid film, and graphite particles were provided on the surface of the PAA liquid film during the drying and solidifying thereof, so as to obtain a graphite layer on the outer surface and a graphite particle permeation region in the organic film layer. The graphite heat conductive layer had a thickness of 0.005 mm. The PAA liquid film was solidified, subsequently stretched, and dehydrated and catalyzed, so as to obtain a PI film with a total thickness of 0.012 mm (including the thickness of the graphite particle permeation region). The PI film was die cut into a strip with a width of 2 mm.

(4) A black matte ink layer with a thickness of 0.004 mm was printed on the surface of the graphite heat conductive layer by transfer printing. Thus, an insulating protection layer with a total thickness of 0.021 mm was formed.

(5) The surface of the insulating protection layer without the black matter ink layer was adhered to the acrylic adhesive layer, such that in the width direction, the distance between the edge of the first end and the edge of the aluminum foil at this end was 0.6 mm, and the distance between the edge of the second end and the edge of the aluminum foil at that end was 32.4 mm.

### Example 2

A composite adhesive tape as shown in FIG. 8 was prepared by the following steps.

(1) An aluminum foil with a thickness of 0.036 mm was prepared. The aluminum foil was die cut into a strip with a width of 35 mm.

(2) A solution of PAA was cast on a flat plate to form a PAA liquid film, and graphite particles were provided on the surface of the PAA liquid film during the drying and solidifying thereof, so as to obtain a graphite layer on the outer surface and a graphite particle permeation region in the organic film layer. The graphite heat conductive layer had a thickness of 0.005 mm. The PAA liquid film was solidified, subsequently stretched, and dehydrated and catalyzed, so as to obtain a PI film with a total thickness of 0.012 mm (including the thickness of the graphite particle permeation region). The PI film is die cut into a strip with a width of 2 mm.

(3) A black matte ink layer with a thickness of 0.004 mm was printed on the surface of the graphite heat conductive layer by transfer printing. Thus, an insulating protection layer with a total thickness of 0.021 mm was formed.

(4) The surface of the insulating protection layer without the black matter ink layer was adhered to the aluminum foil by hot pressing, such that in the width direction, the distance between the edge of the first end and the edge of the aluminum foil at this end was 0.6 mm, and the distance between the edge of the second end and the edge of the aluminum foil at that end was 32.4 mm.

(5) An anisotropic electrically conductive acrylic adhesive layer with a thickness of 0.014 mm was applied on the aluminum foil and the insulating protection layer. The acrylic adhesive layer was completely overlapped with the aluminum foil.

### Example 3

A display device as a display unit for splicing was prepared by the following steps.

(1) A rectangular display device comprising a 46-inch display panel, an intermediate frame supporting the display panel and a back plate was prepared. A circuit drive flexible circuit board with a thickness of 0.1 mm was provided on at least one side edge end surface of the display panel, and a black matrix of 0.67 mm (i.e., the width of the non-display area of the display panel) was provided on this side edge. No flexible circuit board was provided on the opposite side edge end surface, and a black matrix of 0.57 mm was provided on that side edge. In the thickness direction of the display panel, one end of the flexible circuit board protruded from the back surface of the display panel, while the other end did not protrude from the light-exiting surface of the display panel, and its edge was separated from the edge of the light-exiting surface at a distance of 0.6 mm.

(2) The edge of the first end of the composite adhesive tape prepared in Example 1 was manually aligned with a baseline on the back plate of the display device, and was adhered to the side edge end surface by pressing. The baseline was configured such that the edge of the first end of the insulating protection layer was disposed between the edge of the flexible circuit board and the light-exiting surface of the display panel after adhering, and was separated from the edge of the flexible circuit board at a distance of 0.2 mm. After adhering of the side edge end surface was finished, the portion of the composite adhesive tape exceeding the light-exiting surface of the display panel (about 0.2 mm) was bent to the light-exiting surface of the display panel, and was adhered to the light-exiting surface of the display panel.

(3) Step (2) was repeated, so that all the side edge end surfaces were covered by the composite adhesive tape.

Subsequently, the display device was subjected to a high temperature and high humidity environment test (60° C., 90% humidity) for 10 days. After the test, no glue failure or short circuit occurred, and no poor picture display occurred.

The drive flexible circuit board with the composite adhesive tape adhered was subjected to a temperature rise test and ΔT was 21° C. In contrast, the result of the temperature rise test for the drive flexible circuit board without the composite adhesive tape adhered showed a ΔT of 36° C.

### Example 4

A display device was prepared in the same process as that in Example 3, except that the composite adhesive tape prepared in Example 2 was used.

A similar performance test was carried out, and the result was similar to that in Example 3.

### Example 5

Two display devices were prepared according to Example 3. The two display devices were spliced such that a side edge end surface of one display device provided with a flexible circuit board was spliced with a side edge end surface of the other display device without a flexible circuit board to form a spliced display apparatus.

The resultant display apparatus had a splice seam width of 0.67 mm (a black matrix)+0.036 mm (an aluminum foil)+0.014 mm (an acrylic layer)+0.021 mm (an insulating protection layer)+0.1 mm (a flexible circuit board)+0.57 mm (a black matrix)+0.036 mm (an aluminum foil)+0.014 mm (an acrylic layer)+0.021 mm (an insulating protection layer)=1.482 mm. The splice seam width is significantly less than the splice seam width in the related art.

### Example 6

Two display devices were prepared according to Example 4 and spliced as Example 5. Like in Example 5, a splice seam width of 1.482 mm may be obtained.

### Example 7

A composite adhesive tape was prepared according to the process of Example 1, except that an acrylic adhesive layer with a thickness of 0.014 mm was further applied after printing a black matter ink layer.

The resultant composite adhesive tape was used for preparing a spliced display apparatus according to Examples 3 and 5, obtaining a splice seam width of 1.51 mm, which is also less than the splice seam width in the related art.

As can be seen from the Examples, the present disclosure provides a composite adhesive tape, which has a particular step structure and is easy to operate. The composite adhesive tape may easily achieve electrical conduction and reliable insulating protection on the bonding region of the flexible circuit board by a single adhering operation, and provide good heat conduction function. That is, the present disclosure may achieve technical effects of simplifying the adhering operation, increasing the production efficiency for the splicing display device, and increasing the yield for the adhesive tape adhering. The composite adhesive tape of the present disclosure may also provide good light shield function. Furthermore, a smaller splice seam width may be achieved while the display performance is maintained by using the composite adhesive tape of the present disclosure, thereby enabling a large area display with better display quality. The display devices of the present disclosure may be easily obtained manually, and may ensure good heat dissipation, electrical conduction and insulating property, and the display apparatus formed by splicing them has a narrow splice seam and reliable performance.

The above descriptions are only particular embodiments of the present disclosure, but the protection scope of the present disclosure is not limited thereto. Within the technical scope disclosed in the present disclosure, one skilled in the art can readily envisage variations and alternatives, and all of them are covered by the protection scope of the present disclosure. Therefore, the protection scope of the present disclosure should be defined by the appended claims.

1. A display device comprising:
a display panel having a light-exiting upper surface, a lower surface opposite to the light-exiting upper surface and a plurality of side edge end surfaces between the light-exiting upper surface and the lower surface, wherein the display panel comprises a first group of bonding electrodes at a side where a first side edge end surface in the plurality of side edge end surfaces is located;
a first flexible circuit board electrically connected to the first group of bonding electrodes, wherein an upper edge of the first flexible circuit board is lower than an upper edge of the first side edge end surface;
a first insulating protection layer at a side of the first flexible circuit board away from the first group of bonding electrodes, wherein an upper edge of the first insulating protection layer is higher than the upper edge of the first flexible circuit board, and a lower edge of the first insulating protection layer is lower than the first group of bonding electrodes;
a first conductive layer comprising a first portion extending along the light-exiting upper surface of the display panel and a second portion extending along the first side edge end surface, wherein the first insulating protection layer is between the second portion and the first flexible circuit board; and
a first adhesive layer at a side of the first conductive layer close to the display panel, wherein the first insulating protection layer is between the first adhesive layer and the first flexible circuit board or between the first adhesive layer and the first conductive layer.

2. The display device according to claim 1, wherein the first insulating protection layer comprises an organic insulating film and a heat conductive layer at a side of the organic insulating film close to the first flexible circuit board.

3. The display device according to claim 2, wherein a material for the heat conductive layer comprises one or more selected from the group consisting of carbon particles, silica gel and heat conductive oil.

4. The display device according to claim 2, wherein the heat conductive layer has a thickness in a range from 0.003 mm to 0.01 mm.

5. The display device according to claim 2, wherein the organic insulating film comprises a heat conductive filler permeation region within the organic insulating film and at a side of the organic insulating film close to the heat conductive layer,
wherein the heat conductive filler permeation region comprises a heat conductive filler which is the same as a material for the heat conductive layer.

6. The display device according to claim 2, wherein a material for the organic insulating film comprises polyimide.

7. The display device according to claim 2, wherein the organic insulating film has a thickness in a range from 0.008 mm to 0.014 mm.

8. (canceled)

9. The display device according to claim 1, wherein a material for the first conductive layer comprises aluminum; and
the first conductive layer is in direct contact with the first insulating protection layer.

10. The display device according to claim 1, wherein a total width of the first conductive layer between the upper edge of the first insulating protection layer and an upper end of the conductive layer is in a range from 0.2 mm to 1.4 mm.

11. The display device according to claim 1, wherein a distance between the upper edge of the first insulating protection layer and the upper edge of the first flexible circuit board is greater than or equal to 0.1 mm.

12. The display device according to claim 1, wherein a distance between the upper edge and the lower edge of the first insulating protection layer is greater than or equal to 1.6 mm.

13. (canceled)

14. The display device according to claim 1, wherein the first adhesive layer is electrically conductive in its thickness direction and electrically insulating in its extending direction.

15. (canceled)

16. The display device according to claim 1, wherein the display panel has a rectangular outer contour and has 4 side edges comprising a first side edge having the first side edge end surface and a second side edge that is adjacent to the first side edge and has a second side edge end surface, and the display panel further comprises a second group of bonding electrodes at a side where the second side edge end surface is located;
wherein the display device comprises:
a second flexible circuit board electrically connected to the second group of bonding electrodes, wherein an upper edge of the second flexible circuit board is lower than an upper edge of the second side edge end surface;
a second insulating protection layer at a side of the second flexible circuit board away from the second group of bonding electrodes, wherein an upper edge of the second insulating protection layer is higher than the upper edge of the second flexible circuit board, and a lower edge of the second insulating protection layer is lower than the second group of bonding electrodes;
a second conductive layer comprising a first portion extending along the light-exiting upper surface of the display panel and a second portion extending along the second side edge end surface, wherein the second insulating protection layer is between the second portion of the second conductive layer and the second flexible circuit board; and
a third adhesive layer at a side of the second conductive layer close to the display panel, wherein the second insulating protection layer is between the third adhesive layer and the second flexible circuit board or between the third adhesive layer and the second conductive layer; and
wherein the display panel comprises a data line extending along the second side edge and a gate line extending along the first side edge, wherein the data line is connected to the first group of bonding electrodes, and the gate line is connected to the second group of bonding electrodes.

17. (canceled)

18. A display apparatus, wherein the display apparatus is formed by splicing a plurality of display devices according to claim 1, and light-exiting upper surfaces of the plurality of display devices are in the same plane.

19. A composite adhesive tape for a display device comprising:
a conductive layer;
an insulating protection layer at a side of the conductive layer, wherein in at least one direction in which the conductive layer extends, at least one side edge of the insulating protection layer exhibits retraction relative to a corresponding side edge of the conductive layer; and
a first adhesive layer at a side of the insulating protection layer away from the conductive layer or between the conductive layer and the insulating protection layer.

20. The composite adhesive tape for a display device according to claim 19, wherein the insulating protection layer comprises an organic insulating film and a heat conductive layer at a side of the organic insulating film away from the conductive layer.

21. The composite adhesive tape for a display device according to claim 20, wherein the organic insulating film is a polyimide film.

22. (canceled)

23. The composite adhesive tape for a display device according to claim 19, wherein a material for the conductive layer comprises aluminum; and
the conductive layer is in direct contact with the insulating protection layer.

24. The composite adhesive tape for a display device according to claim 19, wherein a distance of the retraction is in a range from 0.2 mm to 1.4 mm.

25. The composite adhesive tape for a display device according to claim 19, wherein a width of the insulating protection layer in a direction of the retraction is greater than or equal to 1.6 mm.
